(19) United States
(12) Patent Application Publication
(10) Pub. No.: US 2015/0371875 A1
(43) Pub. Date: Dec. 24, 2015

(54) SUBSTRATE PROCESSING APPARATUS

(71) Applicant: HITACHI KOKUSAI ELECTRIC INC., Tokyo (JP)

(72) Inventors: Takafumi SASAKI, Toyama-shi (JP); Tetsuo YAMAMOTO, Toyama-shi (JP)

(73) Assignee: HITACHI KOKUSAI ELECTRIC INC., Tokyo (JP)

(21) Appl. No.: 14/747,783

(22) Filed: Jun. 23, 2015

(30) Foreign Application Priority Data
Jun. 24, 2014 (JP) 2014-128987

(51) Int. Cl. H01L 21/67; B08B 5/02

(52) U.S. Cl. CPC H01L 21/67017; B08B 5/02

(57) ABSTRACT

Cleaning processing of each of the inside of a shower head and the inside of a processing space can be sufficiently or appropriately performed even when gas supply is performed via the shower head. A substrate processing apparatus includes a processing space for processing a substrate, a shower head buffer chamber disposed adjacent to the processing space with a dispersion plate having through-holes therebetween, an inert gas supply system configured to supply an inert gas into the shower head buffer chamber to form a gas curtain in the shower head buffer chamber, a first cleaning gas supply system configured to supply a cleaning gas into the processing space, and a control member configured to control the inert gas supply system and the first cleaning gas supply system to concurrently supply the cleaning gas into the processing space and the inert gas into the shower head buffer chamber.

### CROSS-REFERENCE TO RELATED PATENT APPLICATION

This U.S. non-provisional patent application claims priority under 35 U.S.C. §119 of Japanese Patent Application No. 2014-128987, filed on Jun. 24, 2014, in the Japanese Patent Office, the entire contents of which are hereby incorporated by reference.

### BACKGROUND OF THE INVENTION

1. Field of the Invention

The present invention relates to a substrate processing apparatus.

2. Description of the Related Art

In a process of manufacturing a semiconductor device, various process processing is performed on a substrate such as a wafer or the like. In the process processing, for example, there is film-forming processing performed by an alternate supply method. The alternate supply method is a method of alternately supplying at least two types of processing gases such as a source gas and a reactive gas that reacts with the source gas to a substrate serving as a processing target, and reacting the gases on a surface of the substrate to form and deposit a layer one by one to form a film having a desired film thickness. In the alternate supply method, a purge gas that removes a remaining gas during supply of each processing gas may be provided not to cause the source gas to react with the reactive gas at a place except for the surface of the substrate.

As a type of the substrate processing apparatus for performing the film-forming processing by the alternate supply method, for example, a single type substrate processing apparatus including a shower head may be provided. The shower head is disposed at an upper side of a processing surface of a substrate to uniformly supply a processing gas onto the substrate processing surface. The shower head includes a dispersion plate disposed at a position opposite to the processing surface of the substrate and including a plurality of through-holes. A gas supply system is connected to an upper side of the shower head, and the shower head is configured to include a gas guide between a gas supply hole, to which the gas supply system is connected, and the dispersion plate. The gas guide is formed in a conical shape increased from the gas supply hole serving as a starting point toward an outer circumference of the dispersion plate. In the substrate processing apparatus including the shower head having the above-mentioned configuration, since the gas guide guides a gas supplied through the gas supply hole to be diffused toward the dispersion plate, a diffusion level of the gas or density of the gas may be uniformized at a central section of the dispersion plate and an outer circumferential section of the dispersion plate. Accordingly, since the gas that starts to be supplied can substantially concurrently arrive at the central section and the outer circumferential section of the dispersion plate, supply of the gas onto the processing surface of the substrate can be realized with high uniformity.

While the source gas and the reactive gas are alternately supplied as described above when the film-forming processing by the alternate supply method is performed, a remaining gas in the shower head may react to generate reaction byproducts in the shower head when the gas supply is performed via the shower head. Unlike the processing space under the dispersion plate, the inside of the shower head cannot satisfy a temperature condition or a pressure condition under which a film is formed. Accordingly, a film having poor properties such as deviations in film density, film thickness, or the like, is formed as reaction byproducts in the shower head. Such reaction byproducts may be easily delaminated due to pressure fluctuation or the like when the gas supply is switched. The delaminated byproducts may intrude into the processing space to exert a bad influence to film properties on the substrate or cause a decrease in yield rate.

The reaction byproducts in the shower head may be manually removed by an operator upon maintenance of the apparatus. However, in this case, a downtime may be remarkably increased to decrease operation efficiency of the apparatus.

In order to remove the reaction byproducts without a decrease in operation efficiency of the apparatus as possible, a method of using a cleaning gas may be provided. Specifically, the cleaning gas is supplied into the processing space via the shower head to perform the cleaning processing in the shower head and in the processing space. However, in this case, since the cleaning gas is deactivated during a process of sequentially flowing through the inside of the shower head and the inside of the processing space, the cleaning processing may be insufficient at a downstream side in a direction in which a gas in the processing space flows. In this respect, a countermeasure method of respectively performing the cleaning processing in which the cleaning gas is supplied into the processing space via the shower head and performing the cleaning processing in which the cleaning gas is reversely supplied from the processing space toward the shower head may be considered. However, when the cleaning processing is respectively performed, since the cleaning gas, which is active in each cleaning processing, passes through the inside of the gas guide (a processing space side) included in the shower head, over-etching may occur.

### SUMMARY OF THE INVENTION

Accordingly, the present invention is directed to provide a substrate processing apparatus and a method of manufacturing a semiconductor device that are capable of sufficiently and appropriately performing cleaning processing with respect to the inside of a shower head and the inside of a processing space when gas supply is performed via the shower head.

According to an aspect of the present invention, there is provided a substrate processing apparatus including: a processing space for processing a substrate; a shower head buffer chamber disposed adjacent to the processing space with a dispersion plate having through-holes therebetween; an inert gas supply system configured to supply an inert gas into the shower head buffer chamber to form a gas curtain in the shower head buffer chamber; a first cleaning gas supply system configured to supply a cleaning gas into the processing space; and a control member configured to control the inert gas supply system and the first cleaning gas supply system to concurrently supply the cleaning gas into the processing space and the inert gas into the shower head buffer chamber.

### BRIEF DESCRIPTION OF THE DRAWINGS

FIG. 1 is a schematic configuration view of a single type substrate processing apparatus according to a first embodiment of the present invention;

FIG. 2 is a flowchart showing a substrate processing process and a cleaning process according to the first embodiment of the present invention;

FIG. 3 is a flowchart showing a film-forming process of FIG. 2 in detail;

FIG. 4 is a time chart showing a detailed sequence of the cleaning process according to the first embodiment of the present invention;

FIG. 5 is a view for schematically describing a flow of a cleaning gas in the cleaning process according to the first embodiment of the present invention;

FIG. 6 is a time chart showing a detailed sequence of a cleaning process according to a second embodiment of the present invention;

FIG. 7 is a view for schematically describing a flow of a cleaning gas in the cleaning process according to the second embodiment of the present invention;

FIG. 8 is a time chart showing a detailed sequence of a cleaning process according to a third embodiment of the present invention;

FIG. 9 is a view schematically showing a flow of a cleaning gas in the cleaning process according to the third embodiment of the present invention;

FIG. 10 is a time chart showing a detailed sequence of a cleaning process according to a fourth embodiment of the present invention;

FIG. 11 is a view schematically showing a flow of a cleaning gas in the cleaning process according to the fourth embodiment of the present invention; and

FIG. 12 is a time chart showing a detailed sequence of a cleaning process according to a fifth embodiment of the present invention.

### DETAILED DESCRIPTION OF THE PREFERRED EMBODIMENTS

Hereinafter, a first embodiment of the present invention will be described.

### (1) Configuration of Substrate Processing Apparatus

A substrate processing apparatus according to the embodiment is configured as a single type substrate processing apparatus for performing processing on a substrate serving as a processing target one by one. The substrate serving as the processing target may be, for example, a semiconductor wafer substrate manufactured as a semiconductor device (hereinafter, simply referred to as a “wafer”). While etching, ashing, film-forming processing and so on may be exemplarily performed as the processing performed on the substrate, in particular, the film-forming processing is performed in the embodiment. Alternate supply processing is a typical example of the film-forming processing.

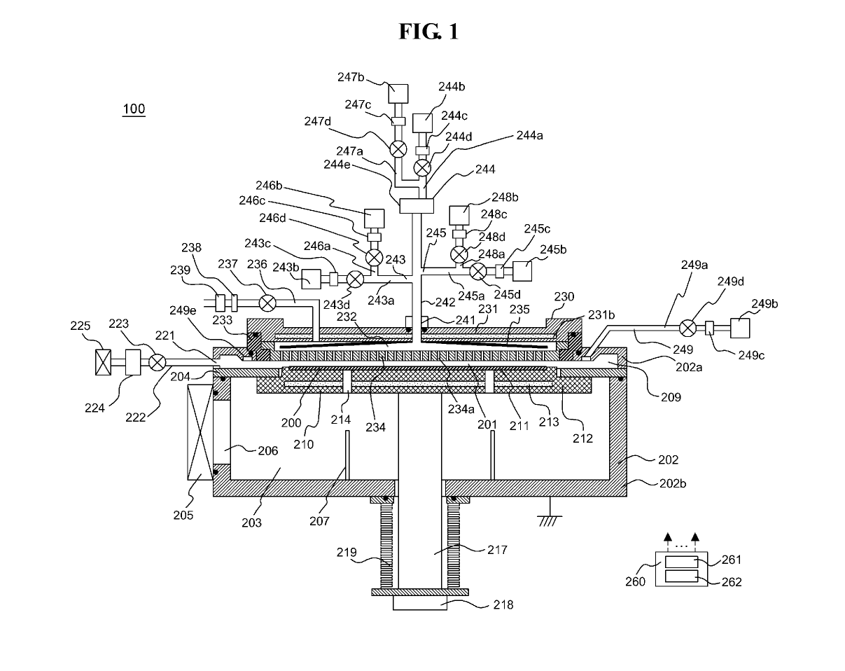

Hereinafter, a configuration of the substrate processing apparatus according to the embodiment will be described with reference to FIG. 1. FIG. 1 is a schematic configuration view of the single type substrate processing apparatus according to the embodiment.

(Processing Container)

As shown in FIG. 1, a substrate processing apparatus 100 includes a processing container 202. The processing container 202 is configured as, for example, a flat sealing container having a circular cross section. In addition, the processing container 202 is formed of a metal material such as aluminum (Al), stainless steel (SUS) or the like. A processing space 201 in which a wafer 200 such as a silicon wafer or the like serving as a substrate is processed and a conveyance space 203 through which the wafer 200 passes when the wafer 200 is conveyed into the processing space 201 are formed in the processing container 202. The processing container 202 is constituted by an upper container 202a and a lower container 202b. A partition plate 204 is installed between the upper container 202a and the lower container 202b.

An exhaust buffer chamber 209 is installed in the vicinity of an edge of an outer circumference in the upper container 202a. The exhaust buffer chamber 209 functions as a buffer space when a gas in the processing space 201 is discharged toward lateral surroundings. Accordingly, the exhaust buffer chamber 209 includes a space formed to surround an outer lateral circumference of the processing space 201. That is, the exhaust buffer chamber 209 includes a space formed in a ring shape (an annular shape) at an outer circumferential side of the processing space 201 when seen in a plan view. A space included in the exhaust buffer chamber 209 is defined by a ceiling surface and both wall surfaces of the upper container 202a and a bottom surface of the partition plate 204. In addition, an inner circumferential side of the space is configured to come in communication with the processing space 201 such that a gas supplied into the processing space 201 is introduced into the exhaust buffer chamber 209 via the communication place.

A substrate loading outlet 206 adjacent to a gate valve 205 is installed at a side surface of the lower container 202b, and the wafer 200 moves between conveyance chambers (not shown) via the substrate loading outlet 206. A plurality of lift pins 207 are installed at a bottom section of the lower container 202b. In addition, the lower container 202b is grounded.

(Substrate Support Member)

A substrate support member 210 configured to support the wafer 200 is installed in the processing space 201. The substrate support member 210 mainly includes a substrate placing surface 211 on which the wafer 200 is placed, a substrate placing table 212 having the substrate placing surface 211 on a surface thereof, and a heater 213 serving as a heating source installed in the substrate placing table 212. Through-holes 214 through which the lift pins 207 pass are installed at the substrate placing table 212 at positions corresponding to the lift pins 207, respectively.

The substrate placing table 212 is supported by a shaft 217. The shaft 217 passes through the bottom section of the processing container 202, and is connected to an elevation mechanism 218 outside the processing container 202. As the elevation mechanism 218 is operated to elevate the shaft 217 and the substrate placing table 212, the wafer 200 placed on the substrate placing surface 211 can be elevated. In addition, surroundings of a lower end of the shaft 217 are coated with a bellows 219, and the inside of the processing container 202 is hermetically retained.

The substrate placing table 212 is lowered to a position (a wafer conveyance position) at which the substrate placing surface 211 is opposite to the substrate loading outlet 206 upon conveyance of the wafer 200, and raised until the wafer 200 arrives at a processing position (a wafer processing position) in the processing space 201 when the wafer 200 is processed. Specifically, when the substrate placing table 212 is lowered to the wafer conveyance position, upper end sections of the lift pins 207 are configured to protrude from an upper surface of the substrate placing surface 211 such that the lift pins 207 supports the wafer 200 from a lower side thereof. In addition, when the substrate placing table 212 is raised to the wafer processing position, the lift pins 207 are withdrawn from the upper surface of the substrate placing surface 211 such that the substrate placing surface 211 supports the wafer 200 from the lower side thereof. In addition, since the lift pins 207 come in direct contact with the wafer 200, the lift pins 207 may be formed of a material such as quartz, alumina or the like.

(Shower Head)

A shower head 230 serving as a gas dispersion mechanism is installed over the processing space 201 (at an upstream side in a gas supply direction). A gas introduction port 241 is installed at a lid 231 of the shower head 230, and a gas supply system (to be described below) is connected to the gas introduction port 241. A gas supplied through the gas introduction port 241 is supplied into a shower head buffer chamber 232 serving as a space formed in the shower head 230.

The lid 231 of the shower head 230 is formed of a conductive metal, and used as an electrode configured to generate plasma in the shower head buffer chamber 232 or the processing space 201. An insulating block 233 is installed between the lid 231 and the upper container 202a, and the insulating block 233 insulates the lid 231 from the upper container 202a.

The shower head 230 includes a dispersion plate 234 configured to disperse a gas supplied from the gas supply system via the gas introduction port 241. An upstream side of the dispersion plate 234 is the shower head buffer chamber 232, and a downstream side thereof is the processing space 201. A plurality of through-holes 234a are formed in the dispersion plate 234. The dispersion plate 234 is disposed at an upper side of the substrate placing surface 211 to oppose the substrate placing surface 211. Accordingly, the shower head buffer chamber 232 comes in communication with the processing space 201 through the plurality of through-holes 234a formed in the dispersion plate 234.

A gas guide 235 configured to form a flow of the supplied gas is installed at the shower head buffer chamber 232. The gas guide 235 has a conical shape having a diameter increased in a direction of the dispersion plate 234 from the gas introduction port 241 serving as an apex. The gas guide 235 is formed such that a lower end thereof is disposed closer to an outer circumferential side than the through-hole 234a formed at the outermost circumferential side of the dispersion plate 234. That is, the shower head buffer chamber 232 includes the gas guide 235 configured to guide the gas supplied through an upper side of the dispersion plate 234 toward the processing space 201.

In addition, the shower head 230 may include a heater 231b serving as a heating source configured to increase a temperature in the shower head buffer chamber 232 and the processing space 201. In addition, an impedance matching box and a high frequency power supply (which are not shown) are connected to the lid 231 of the shower head 230, and plasma may be generated in the shower head buffer chamber 232 and the processing space 201 as impedance is adjusted by the impedance matching box and the high frequency power supply.

(Gas Supply System)

A common gas supply pipe 242 is connected to the gas introduction port 241 formed in the lid 231 of the shower head 230. The common gas supply pipe 242 comes in communication with the shower head buffer chamber 232 in the shower head 230 as the common gas supply pipe 242 is connected to the gas introduction port 241. In addition, a first gas supply pipe 243a, a second gas supply pipe 244a and a third gas supply pipe 245a are connected to the common gas supply pipe 242. The second gas supply pipe 244a is connected to the common gas supply pipe 242 via a remote plasma member (a Remote Plasma Unit, RPU) 244e.

A source gas is mainly supplied through a source gas supply system 243 including the first gas supply pipe 243a, and a reactive gas is mainly supplied through a reactive gas supply system 244 including the second gas supply pipe 244a. Either an inert gas or a cleaning gas is supplied through an inert gas supply system 245 including the third gas supply pipe 245a.

In addition, in the gases supplied into the shower head buffer chamber 232 of the shower head 230 through the common gas supply pipe 242, the source gas may be referred to as a first gas, the reactive gas may be referred to as a second gas, the inert gas may be referred to as a third gas, and the cleaning gas may be referred to as a fourth gas. In addition, a cleaning gas supplied by a first cleaning gas supply system (a gas supply system configured to supply a cleaning gas into the processing space), which will be described below, serving as another one of the gas supply systems may be referred to as a fifth gas.

(Source Gas Supply System)

A source gas supply source 243b, a mass flow controller (MFC) 243c serving as a flow rate controller (a flow rate control member) and a valve 243d serving as an opening/closing valve are installed at the first gas supply pipe 243a in sequence from an upstream direction. In addition, the source gas serving as the first gas is supplied into the shower head buffer chamber 232 via the MFC 243c, the valve 243d and the common gas supply pipe 242 through the first gas supply pipe 243a.

The source gas is one of the processing gases, for example, Si₂Cl₆ (disilicon hexachloride or hexachlorodisilane) gas (i.e., Si₂Cl₆ gas) serving as a source material including Si (silicon) element. In addition, the source gas may be any one of a solid, a liquid and a gas at a normal temperature and a normal pressure. When the source gas is the liquid at the normal temperature and the normal pressure, a vaporizer (not shown) may be installed between the source gas supply source 243b and the MFC 243c. Here, the source gas will be described as the gas.

Mainly, the source gas supply system 243 is constituted by the first gas supply pipe 243a, the MFC 243c and the valve 243d. In addition, the source gas supply system 243 may include the source gas supply source 243b and a first inert gas supply system, which will be described below. In addition, the source gas supply system 243 corresponds to one of the processing gas supply systems because the source gas, which is one of the processing gases, is supplied therethrough.

A downstream end of a first inert gas supply pipe 246a is connected to the first gas supply pipe 243a at a downstream side of the valve 243d. An inert gas supply source 246b, a mass flow controller (MFC) 246c serving as a flow rate controller (a flow rate control member) and a valve 246d serving as an opening/closing valve are installed at the first inert gas supply pipe 246a in sequence from an upstream direction. In addition, an inert gas is supplied into the shower head buffer chamber 232 via the MFC 246c, the valve 246d and the first gas supply pipe 243a through the first inert gas supply pipe 246a.

Since the inert gas serves as a carrier gas of the source gas, a gas that does not react with the source material may be used as the inert gas. Specifically, for example, nitrogen (N₂) gas may be used. In addition, a rare gas such as helium (He) gas, neon (Ne) gas, argon (Ar) gas or the like may be used in addition to N₂ gas.

Mainly, a first inert gas supply system is constituted by the first inert gas supply pipe 246a, the MFC 246c and the valve 246d. In addition, the first inert gas supply system may include the inert gas supply source 246b and the first gas supply pipe 243a. In addition, the first inert gas supply system may be included in the source gas supply system 243.

(Reactive Gas Supply System)

The RPU 244e is installed at a downstream side of the second gas supply pipe 244a. A reactive gas supply source 244b, a mass flow controller (MFC) 244c serving as a flow rate controller (a flow rate control member) and a valve 244d serving as an opening/closing valve are installed at an upstream side thereof from an upstream direction. In addition, the reactive gas serving as the second gas is supplied into the shower head buffer chamber 232 via the MFC 244c, the valve 244d, the RPU 244e and the common gas supply pipe 242 through the second gas supply pipe 244a. The reactive gas becomes a plasma state by the remote plasma member 244e, and is radiated onto the wafer 200 in the processing space 201 via the plurality of through-holes 234a formed in the dispersion plate 234.

The reactive gas is one of the processing gases, and for example, ammonia (NH₃) gas is used as the reactive gas.

Mainly, the reactive gas supply system 244 is constituted by the second gas supply pipe 244a, the MFC 244c and the valve 244d. In addition, the reactive gas supply system 244 may include the reactive gas supply source 244b, the RPU 244e and a second inert gas supply system, which will be described below. In addition, the reactive gas supply system 244 corresponds to another one of the processing gas supply systems because the reactive gas, one of the processing gases, is supplied therethrough.

A downstream end of a second inert gas supply pipe 247a is connected to the second gas supply pipe 244a at a downstream side of the valve 244d. An inert gas supply source 247b, a mass flow controller (MFC) 247c serving as a flow rate controller (a flow rate control member) and a valve 247d serving as an opening/closing valve are installed at the second inert gas supply pipe 247a in sequence from an upstream direction. In addition, the inert gas is supplied into the shower head buffer chamber 232 via the MFC 247c, the valve 247d, the second gas supply pipe 244a and the RPU 244e through the second inert gas supply pipe 247a.

The inert gas serves as a carrier gas or a dilution gas of the reactive gas. Specifically, for example, nitrogen (N₂) gas may be used as the inert gas. In addition, a rare gas such as helium (He) gas, neon (Ne) gas, argon (Ar) gas or the like may be used in addition to N₂ gas.

Mainly, a second inert gas supply system is constituted by the second inert gas supply pipe 247a, the MFC 247c and the valve 247d. In addition, the second inert gas supply system may include the inert gas supply source 247b, the second gas supply pipe 244a and the RPU 244e. In addition, the second inert gas supply system may be included in the reactive gas supply system 244.

(Insert Gas Supply System)

An inert gas supply source 245b, a mass flow controller (MFC) 245c serving as a flow rate controller (a flow rate control member) and a valve 245d serving as an opening/closing valve are installed at the third gas supply pipe 245a in sequence from an upstream direction. In addition, the inert gas serving as a purge gas in a film-forming process (to be described below) is supplied into the shower head buffer chamber 232 via the MFC 245c, the valve 245d and the common gas supply pipe 242 through the third gas supply pipe 245a. In addition, the inert gas serving as a carrier gas or a dilution gas of the cleaning gas is supplied into the shower head buffer chamber 232 via the MFC 245c, the valve 245d and the common gas supply pipe 242 in a first cleaning process (to be described below) according to necessity. In addition, the inert gas for forming a gas curtain in the shower head buffer chamber 232 is supplied into the shower head buffer chamber 232 via the MFC 245c, the valve 245d and the common gas supply pipe 242 in a second cleaning process (to be described below).

The inert gas supplied from the inert gas supply source 245b serves as a purge gas for purging the gas remaining in the processing container 202 or the shower head 230 in the film-forming process. In addition, the inert gas may serve as the carrier gas or the dilution gas of the cleaning gas in the first cleaning process. In addition, the inert gas is used to form a gas curtain in the shower head buffer chamber 232 in the second cleaning process. Specifically, for example, nitrogen (N₂) gas may be used as the inert gas. In addition, a rare gas such as helium (He) gas, neon (Ne) gas, argon (Ar) gas or the like may be used in addition to N₂ gas.

Mainly, the inert gas supply system 245 is constituted by the third gas supply pipe 245a, the MFC 245c and the valve 245d. In addition, the inert gas supply system 245 may include the inert gas supply source 245b.

(Second Cleaning Gas Supply System (Gas Supply System Configured to Supply Cleaning Gas into Shower Head Buffer Chamber))

A downstream end of a second cleaning gas supply pipe 248a is connected to the third gas supply pipe 245a at a downstream side of the valve 245d. A second cleaning gas supply source 248b, a mass flow controller (MFC) 248c serving as a flow rate controller (a flow rate control member) and a valve 248d serving as an opening/closing valve are installed at the second cleaning gas supply pipe 248a in sequence from an upstream direction. In addition, the cleaning gas is supplied into the shower head buffer chamber 232 via the MFC 248c, the valve 248d and the common gas supply pipe 242 through the third gas supply pipe 245a in the first cleaning process.

The cleaning gas supplied from the second cleaning gas supply source 248b serves as a cleaning gas for removing byproducts or the like stuck to the shower head 230 or the processing container 202 in the first cleaning process. Specifically, for example, trifluoride nitrogen (NF₃) gas may be used as the cleaning gas. In addition, hydrogen fluoride (HF) gas, trifluoride chlorine gas (ClF₃) gas, fluorine (F₂) gas and so on may be solely used or may be combined and used.

Mainly, a second cleaning gas supply system is constituted by the second cleaning gas supply pipe 248a, the MFC 248c and the valve 248d. In addition, the second cleaning gas supply system may include the second cleaning gas supply source 248b and the third gas supply pipe 245a.

(First Cleaning Gas Supply System (Gas Supply System Configured to Supply Cleaning Gas into Processing Space))

The substrate processing apparatus 100 includes a first cleaning gas supply system 249 serving as the gas supply system separately from the second cleaning gas supply system. The first cleaning gas supply system 249 includes a first cleaning gas supply pipe 249a (hereinafter, simply referred to as “a cleaning gas supply pipe”) directly connected to a communication path between the processing space 201 and the exhaust buffer chamber 209. A first cleaning gas supply source 249b, a mass flow controller (MFC) 249c serving as a flow rate controller (a flow rate control member) and a valve 249d serving as an opening/closing valve are installed at the cleaning gas supply pipe 249a in sequence from an upstream direction. In addition, the cleaning gas is supplied into the processing space 201 via the MFC 249c and the valve 249d through the cleaning gas supply pipe 249a in the second cleaning process.

The cleaning gas supplied from the first cleaning gas supply source 249b serves as a cleaning gas for removing byproducts or the like stuck to the processing space 201. Specifically, for example, trifluoride nitrogen (NF₃) gas may be used as the cleaning gas. In addition, for example, hydrogen fluoride (HF) gas, trifluoride chlorine (ClF₃) gas, fluorine (F₂) gas and so on may be solely used or may be combined and used. In addition, the first cleaning gas supply source 249b may not be separately installed from the second cleaning gas supply source 248b when the same kind of cleaning gas as that of the second cleaning gas supply source 248b is supplied, or any one of them may be used in common.

Mainly, the first cleaning gas supply system 249 is constituted by the cleaning gas supply pipe 249a, the MFC 249c and the valve 249d. In addition, the first cleaning gas supply system 249 may include the first cleaning gas supply source 249b.

In addition, the cleaning gas supply pipe 249a may be connected to the communication path between the processing space 201 and the exhaust buffer chamber 209 via a gas supply groove 249e to uniformize supply of the cleaning gas into the processing space 201. The gas supply groove 249e is formed at a communication path ceiling surface between the processing space 201 and the exhaust buffer chamber 209 and extends throughout the entire circumference to be continued in a circumferential direction surrounding the processing space 201. A cross-sectional shape of the groove that forms the gas supply groove 249e is not limited as long as it continues in the circumferential direction but may be an angled groove like an example in the drawing or may be another shape (for example, an annular groove shape).

When the cleaning gas supply pipe 249a is connected via the gas supply groove 249e, the cleaning gas supplied through the cleaning gas supply pipe 249a passes through the gas supply groove 249e to be diffused to the entire circumference and then supplied into the processing space 201 even though only one cleaning gas supply pipe 249a is connected. Accordingly, the cleaning gas can be uniformly supplied into the processing space 201, and the cleaning gas can be prevented from being supplied to a specific place (for example, near a connecting place of the cleaning gas supply pipe 249a) in a concentrated manner. However, when the cleaning gas is uniformly supplied, the cleaning gas supply pipe 249a does not need to be connected via the gas supply groove 249e. For example, if the plurality of cleaning gas supply pipes 249a may be installed, the cleaning gas supply pipes 249a may be connected at a plurality of places, and even in this case, the cleaning gas can be uniformly supplied into the processing space 201.

(Gas Exhaust System)

An exhaust system configured to exhaust atmosphere of the processing container 202 includes a plurality of exhaust pipes connected to the processing container 202, specifically, a basic exhaust pipe (not shown) connected to the conveyance space 203 of the lower container 202b, a first exhaust pipe 236 connected to the shower head buffer chamber 232 of the shower head 230 and a second exhaust pipe 222 connected to the exhaust buffer chamber 209 of the upper container 202a.

(Basic Exhaust System)

The basic exhaust pipe is connected to a side surface or a bottom surface of the conveyance space 203. A turbo molecular pump (TMP, not shown) serving as a vacuum pump configured to provide high-degree vacuum or ultra-high vacuum is installed at the basic exhaust pipe. In addition, a valve (not shown) is installed at the basic exhaust pipe at a downstream side or an upstream side of the TMP, or both sides thereof. In addition, a dry pump (DP, not shown) may be installed at the basic exhaust pipe together with the TMP. The DP functions as an auxiliary pump when the TMP is operated. That is, the TMP and the DP exhaust the atmosphere of the conveyance space 203 via the basic exhaust pipe. In addition, since it is hard for the TMP serving as a high-degree vacuum (or ultra-high vacuum) pump to solely perform exhaust to the atmospheric pressure, the DP serving as an auxiliary pump configured to perform exhaust to the atmospheric pressure is used.

Mainly, the basic exhaust system is constituted by the basic exhaust pipe, the TMP, the DP and the valve.

(First Gas Exhaust System)

The first exhaust pipe 236 is connected to an upper surface or a side surface of the shower head buffer chamber 232. That is, the first exhaust pipe 236 is connected to the shower head 230, and thus, comes in communication with the shower head buffer chamber 232 in the shower head 230. A first valve 237 is installed at the first exhaust pipe 236. In addition, an auto pressure controller (APC) 238 serving as a pressure controller configured to control the inside of the shower head buffer chamber 232 to a predetermined pressure is installed at the first exhaust pipe 236 at a downstream side of the first valve 237. In addition, a vacuum pump 239 is installed at the first exhaust pipe 236 at a downstream side of the APC 238. The vacuum pump 239 exhausts the atmosphere of the shower head buffer chamber 232 via the first exhaust pipe 236.

Mainly, a first gas exhaust system is constituted by the first exhaust pipe 236, the first valve 237, the APC 238 and the vacuum pump 239. In addition, the vacuum pump 239 may commonly use the DP of the basic exhaust system.

(Second Gas Exhaust System)

The second exhaust pipe 222 is connected to the inside of the exhaust buffer chamber 209 via an exhaust hole 221 installed at an upper surface or a side surface of the exhaust buffer chamber 209. A second valve 223 is installed at the second exhaust pipe 222. In addition, an APC 224 serving as a pressure controller configured to control the inside of the processing space 201 in communication with the exhaust buffer chamber 209 to a predetermined pressure is installed at the second exhaust pipe 222 at a downstream side of the second valve 223. In addition, a vacuum pump 225 is installed at the second exhaust pipe 222 at a downstream side of the APC 224. The vacuum pump 225 exhausts the atmosphere of the exhaust buffer chamber 209 and the processing space 201 in communication therewith via the second exhaust pipe 222.

Mainly, a second gas exhaust system is constituted by the second exhaust pipe 222, the second valve 223, the APC 224 and the vacuum pump 225. In addition, the vacuum pump 225 may commonly use the DP of the basic exhaust system.

(Controller)

The substrate processing apparatus 100 includes a controller 260 configured to control operations of the respective parts of the substrate processing apparatus 100. The controller 260 includes at least a computation member 261 and a storage member 262. The controller 260 is connected to the respective configurations, and calls a program or a recipe from the storage member 262 according to an instruction of the controller or a user and controls operations of the configurations according to contents thereof. Specifically, the controller 260 controls operations of the gate valve 205, the elevation mechanism 218, the heaters 213 and 231b, the high frequency power supply, the impedance matching box, the MFCs 243c through 249c, the valves 243d through 249d, the APCs 224 and 238, the TMP, the DP, the vacuum pumps 239 and 225, the first valve 237, the second valve 223, and so on.

In addition, the controller 260 may be constituted by a dedicated computer, or may be constituted by a general-purpose computer. For example, the controller 260 according to the embodiment may be configured by preparing an external storage device in which the above-mentioned program is stored (for example, a magnetic tape, a magnetic disk such as a flexible disk, a hard disk or the like, an optical disc such as CD, DVD or the like, an optical magnetic disk such as MO, a semiconductor memory such as a USB memory, a memory card or the like), and installing the program in the general-purpose computer using the external storage device.

In addition, a means configured to supply a program to the computer is not limited to the case in which the program is supplied via the external storage device. For example, the program may be supplied using a communication means such as the Internet or an exclusive line without the external storage device. In addition, the storage member 262 or the external storage device is constituted by a non-transitory computer-readable recording medium. Hereinafter, these are generally and simply referred to as recording media. Further, the term “recording medium” used in the description may include only the storage member 262, only the external storage device, or both of these.

### (2) Substrate Processing Process

Next, a process of forming a thin film on the wafer 200 using the substrate processing apparatus 100 will be described as one process of a method of manufacturing a semiconductor device. In addition, in the following description, operations of the parts that constitute the substrate processing apparatus 100 are controlled by the controller 260.

Here, an example of forming a SiN (silicon nitride) film serving as a silicon-containing film on the wafer 200 using Si₂Cl₆ gas serving as the source gas (the first processing gas) and NH₃ gas serving as the reactive gas (the second processing gas) through the alternate supply method will be described.

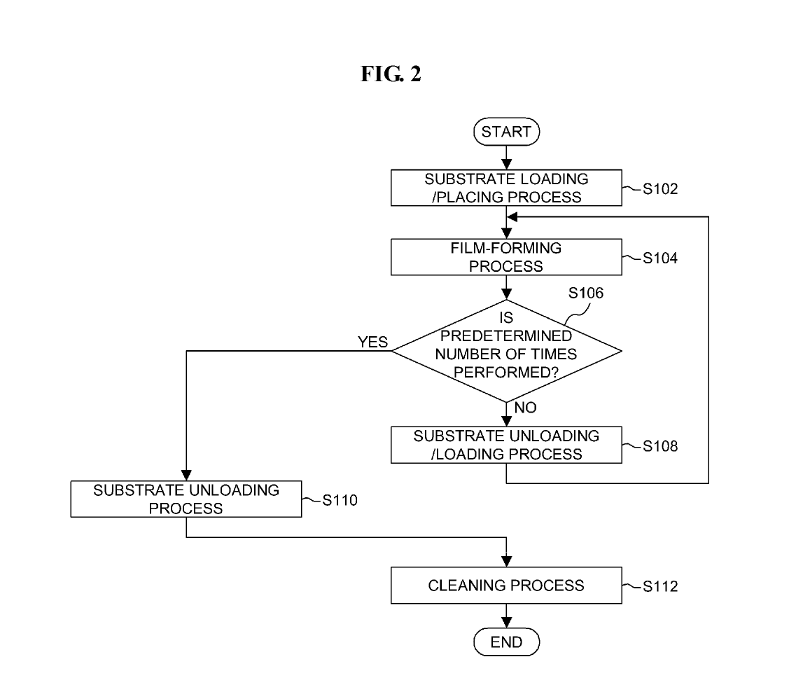

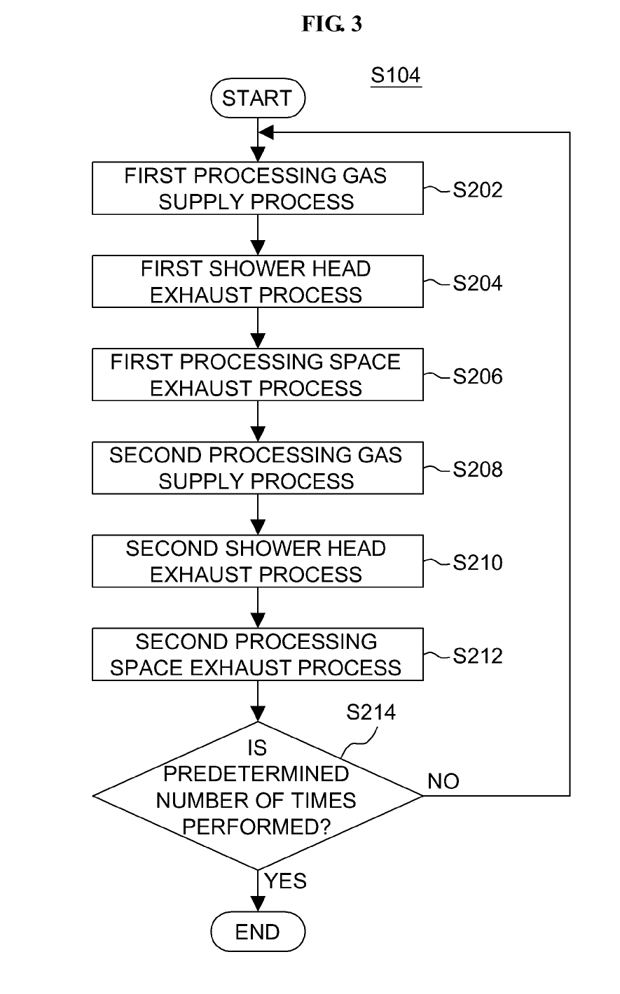

FIG. 2 is a flowchart showing the substrate processing process and the cleaning process according to the embodiment. FIG. 3 is a flowchart showing the film-forming process of FIG. 2 in detail.

(Substrate Loading/Placing Process: S102)

In the substrate processing apparatus 100, first, as the substrate placing table 212 is lowered to the conveyance position of the wafer 200, the lift pins 207 pass through the through-holes 214 of the substrate placing table 212. As a result, the lift pins 207 protrude from the surface of the substrate placing table 212 to a predetermined height. Continuously, the gate valve 205 is opened to bring the conveyance space 203 in communication with a transfer chamber (not shown). In addition, the wafer 200 is loaded into the conveyance space 203 from the transfer chamber using a wafer transferring device (not shown), and the wafer 200 is transferred onto the lift pin 207. Accordingly, the wafer 200 is supported on the lift pins 207 protruding from the surface of the substrate placing table 212 in a horizontal posture.

When the wafer 200 is loaded into the processing container 202, the wafer transferring device is withdrawn to the outside of the processing container 202, and the gate valve 205 is closed to seal the inside of the processing container 202. Then, the wafer 200 is placed on the substrate placing surface 211 installed at the substrate placing table 212 by raising the substrate placing table 212, and the wafer 200 is raised to the processing position in the above-mentioned processing space 201 by raising the substrate placing table 212.

The valve of the basic exhaust system is open (the valve is opened) when the wafer 200 is loaded into the processing container 202, and the TMP comes in communication with the DP while bringing the conveyance space 203 in communication with the TMP. Meanwhile, the valve of the exhaust system except for the valve of the basic exhaust system is closed (the valve is closed). Accordingly, the atmosphere of the conveyance space 203 is exhausted by the TMP and the DP, and the processing container 202 arrives at a high-degree vacuum (ultra-high vacuum) state (for example, 10⁻⁵ Pa or less). Exhausting the processing container 202 to the high-degree vacuum (ultra-high vacuum) state in this process is to reduce a pressure difference between the processing container 202 and the transfer chamber similarly maintained at the high-degree vacuum (ultra-high vacuum) state (for example, 10⁻⁶ Pa or less). In this state, the gate valve 205 is opened, and the wafer 200 is loaded into the conveyance space 203 from the transfer chamber. In addition, the TMP and the DP are always operated in the processes shown in FIGS. 2 and 3 not to cause a delay of the processing process due to the operation start thereof.

After the wafer 200 is loaded into the conveyance space 203, when the wafer 200 is raised to the processing position in the processing space 201, the valve of the basic exhaust system is closed. Accordingly, a space between the conveyance space 203 and the TMP is blocked, and exhaust of the conveyance space 203 by the TMP is terminated. Meanwhile, the second valve 223 of the second gas exhaust system is opened to bring the exhaust buffer chamber 209 in communication with the APC 224 and bring the APC 224 in communication with the vacuum pump 225. The APC 224 controls an exhaust flow rate of the exhaust buffer chamber 209 using the vacuum pump 225 by adjusting conductance of the second exhaust pipe 222 and maintains the processing space 201 in communication with the exhaust buffer chamber 209 at a predetermined pressure. In addition, the valve of the other exhaust system maintains the closed state. In addition, after the valve disposed at the upstream side of the TMP is closed when the valve of the basic exhaust system is closed, the operation of the TMP can be stably maintained by closing the valve disposed at the downstream side of the TMP.

In addition, the N₂ gas serving as the inert gas may be supplied into the processing container 202 through the inert gas supply system 245 while exhausting the inside of the processing container 202 in this process. That is, the N₂ gas may be supplied into the processing container 202 by opening at least the valve 245d of the inert gas supply system 245 while exhausting the inside of the processing container 202 via the exhaust buffer chamber 209 using the TMP or the DP. Accordingly, particles can be suppressed from being stuck onto the wafer 200.

In addition, when the wafer 200 is placed on the substrate placing table 212, power is controlled to be supplied to the heater 213 buried in the substrate placing table 212 such that the surface of the wafer 200 becomes a predetermined processing temperature. Here, the temperature of the heater 213 is adjusted by controlling an electrical connection state to the heater 213 based on temperature information detected by a temperature sensor (not shown).

In this way, in a substrate loading/placing process S102, the inside of the processing space 201 is controlled to become a predetermined processing pressure, and the surface temperature of the wafer 200 is controlled to become a predetermined processing temperature. Here, the predetermined processing temperature and the predetermined processing pressure are a processing temperature and a processing pressure at which a SiN film can be formed by an alternate supply method in a film-forming process S104 (to be described below). That is, the predetermined processing temperature and the predetermined processing pressure are a processing temperature and a processing pressure such that the source gas supplied in a first processing gas (source gas) supply process S202 is not autolyzed. Specifically, the processing temperature may be room temperature to 500° C. or less, preferably, room temperature to 400° C. or less, and the processing pressure may be 50 Pa to 5,000 Pa. The processing temperature and the processing pressure are also maintained in the film-forming process S104 (to be described below).

(Film-Forming Process: S104)

After the substrate loading/placing process S102, the film-forming process S104 is performed. Hereinafter, the film-forming process S104 will be described in detail with reference to FIG. 3. In addition, the film-forming process S104 is cyclic processing in which a process of alternately supplying different processing gases is repeated.

(First Processing Gas Supply Process: S202)

In the film-forming process S104, first, the first processing gas (source gas) supply process S202 is performed. In addition, when the first processing gas is a liquid source material such as TiCl₄ or the like, the source material may be evaporated to generate (preliminarily evaporate) the source gas (for example, TiCl₄ gas). Preliminary evaporation of the source gas may be parallelly performed with the above-mentioned substrate loading/placing process S102. This is because a predetermined time is consumed to stably generate the source gas.

When the source gas (for example, Si₂Cl₆ gas) serving as the first processing gas is supplied, the MFC 243c is adjusted such that a flow rate of the source gas becomes a predetermined flow rate while opening the valve 243d. Accordingly, supply of the source gas into the processing space 201 is started. A supply flow rate of the source gas is, for example, 100 sccm to 500 sccm. The source gas is dispersed by the shower head 230 to be uniformly supplied onto the wafer 200 in the processing space 201.

Here, the valve 246d of the first inert gas supply system is opened to supply an inert gas (N₂ gas) through the first inert gas supply pipe 246a. A supply flow rate of the inert gas is, for example, 500 sccm to 5,000 sccm. In addition, the inert gas may flow through the third gas supply pipe 245a of the inert gas supply system 245.

A surplus source gas is uniformly introduced into the exhaust buffer chamber 209 from the processing space 201, and flows through the second exhaust pipe 222 of the second gas exhaust system to be exhausted. Specifically, the second valve 223 of the second gas exhaust system is open, and the pressure of the processing space 201 is controlled by the APC 224 to become a predetermined pressure. In addition, all of the valves of the exhaust system except for the second valve 223 of the second gas exhaust system are closed.

Here, the processing temperature and the processing pressure in the processing space 201 are a processing temperature and processing pressure at which the source is not autolyzed. For this reason, gas particles of the source gas are adsorbed onto the wafer 200.

After supply of the source gas starts and a predetermined time elapses, the valve 243d of the source gas supply system 243 is closed, and the supply of the source gas is stopped. A supply time of the source gas and the carrier gas is, for example, 2 to 20 seconds.

(First Shower Head Exhaust Process: S204)

After the supply of the source gas is stopped, the inert gas (N₂ gas) is supplied through the third gas supply pipe 245a to purge the shower head buffer chamber 232. Here, in the valves of the gas exhaust system, the second valve 223 of the second gas exhaust system is closed, whereas, the first valve 237 of the first gas exhaust system is open. The valve of the other gas exhaust system is closed. That is, when the purge of the shower head buffer chamber 232 is performed, the space between the exhaust buffer chamber 209 and the APC 224 is blocked to stop the pressure control by the APC 224, and the shower head buffer chamber 232 comes in communication with the vacuum pump 239. Accordingly, the source gas remaining in the shower head 230 (the shower head buffer chamber 232) is exhausted from the inside of the shower head buffer chamber 232 by the vacuum pump 239 via the first exhaust pipe 236. In addition, the valve of the downstream side of the APC 224 may be open.

A supply flow rate of the inert gas (N₂ gas) in a first shower head exhaust process S204 is, for example, 1,000 sccm to 10,000 sccm. In addition, a supply time of the inert gas is, for example, 2 to 10 seconds.

(First Processing Space Exhaust Process: S206)

When the purge of the shower head buffer chamber 232 is terminated, the inert gas (N₂ gas) is supplied through the third gas supply pipe 245a to purge the processing space 201. Here, the second valve 223 of the second gas exhaust system is open, and the pressure of the processing space 201 is controlled by the APC 224 to become a predetermined pressure. Meanwhile, all of the valves of the gas exhaust system except for the second valve 223 are closed. Accordingly, the source gas that is not adsorbed onto the wafer 200 in the first processing gas supply process S202 is removed from the processing space 201 via the second exhaust pipe 222 and the exhaust buffer chamber 209 by the vacuum pump 225 of the second gas exhaust system.

A supply flow rate of the inert gas (N₂ gas) in a first processing space exhaust process S206 is, for example, 1,000 sccm to 10,000 sccm. In addition, a supply time of the inert gas is, for example, 2 to 10 seconds.

In addition, here, while the first processing space exhaust process S206 is performed after the first shower head exhaust process S204, a performing sequence of the processes may be reversed. In addition, these processes may be concurrently performed.

(Second Processing Gas Supply Process: S208)

When the purge of the shower head buffer chamber 232 and the processing space 201 is terminated, a second processing gas (reactive gas) supply process S208 is continuously performed. In the second processing gas supply process S208, the valve 244d is opened, and supply of the reactive gas (NH₃ gas) into the processing space 201 via the remote plasma member 244e and the shower head 230 is started. Here, the MFC 244c is adjusted such that a flow rate of the reactive gas becomes a predetermined flow rate. A supply flow rate of the reactive gas is, for example, 1,000 sccm to 10,000 sccm.

The reactive gas in the plasma state is dispersed by the shower head 230 to be uniformly supplied onto the wafer 200 in the processing space 201, and reacted with a source gas-containing film adhered onto the wafer 200 to form a SiN film on the wafer 200.

Here, the valve 247d of the second inert gas supply system is opened to supply the inert gas (N₂ gas) through the second inert gas supply pipe 247a. A supply flow rate of the inert gas is, for example, 500 sccm to 5,000 sccm. In addition, the inert gas may flow through the third gas supply pipe 245a of the inert gas supply system 245.

The surplus reactive gas or the reaction byproducts are introduced into the exhaust buffer chamber 209 from the processing space 201, and flows through the second exhaust pipe 222 of the second gas exhaust system to be exhausted. Specifically, the second valve 223 of the second gas exhaust system is open, and the pressure of the processing space 201 is controlled by the APC 224 to become a predetermined pressure. In addition, all of the valves of the exhaust system except for the second valve 223 are closed.

After supply of the reactive gas starts and a predetermined time elapses, the valve 244d is closed to stop supply of the reactive gas. A supply time of the reactive gas and the carrier gas is, for example, 2 to 20 seconds.

(Second Shower Head Exhaust Process: S210)

After supply of the reactive gas stops, a second shower head exhaust process S210 is performed to remove the reactive gas or the reaction byproducts remaining in the shower head buffer chamber 232. Since the second shower head exhaust process S210 is performed like the first shower head exhaust process S204, detailed description thereof will be omitted.

(Second Processing Space Exhaust Process: S212)

After purge of the shower head buffer chamber 232 is terminated, a second processing space exhaust process S212 is performed to remove the reactive gas or the reaction byproducts remaining in the processing space 201. Since the second processing space exhaust process S212 is also performed like the first processing space exhaust process S206, detailed description thereof will be omitted.

(Determination Process: S214)

The first processing gas supply process S202, the first shower head exhaust process S204, the first processing space exhaust process S206, the second processing gas supply process S208, the second shower head exhaust process S210 and the second processing space exhaust process S212 are set to one cycle, and the controller 260 determines whether the cycle is performed a predetermined number of times (n cycles) (S214). When the cycles are performed the predetermined number of times, a silicon nitride (SiN) film having a desired film thickness is formed on the wafer 200.

(Processing Number Determination Process: S106)

After the film-forming process S104 constituted by the processes S202 through S214, as shown in FIG. 2, the controller 260 determines whether the number to which the film-forming process S104 is performed arrives at a predetermined number (S106).

When the number of the film-forming processes S104 does not reach the predetermined number, the wafer 200 on which the processing is terminated is discharged, and then, a substrate unloading/loading process S108 is performed to start the processing of a new wafer 200 on standby. In addition, the film-forming process S104 is performed the predetermined number of times, the processed wafer 200 is extracted, and a substrate unloading process S110 is performed such that the wafer 200 is not present in the processing container 202.

(Substrate Unloading/Loading Process: S108)

In the substrate unloading/loading process S108, the substrate placing table 212 is lowered to support the wafer 200 on the lift pins 207 protruding from the surface of the substrate placing table 212. Accordingly, the wafer 200 is moved to the conveyance position from the processing position. Next, the gate valve 205 is opened, and the wafer 200 is unloaded to the outside of the processing container 202 using the wafer transferring device. Here, the valve 245d is closed to stop supply of the inert gas into the processing container 202 by the inert gas supply system 245.

During movement of the wafer 200 from the processing position to the conveyance position in the substrate unloading/loading process S108, the second valve 223 of the second gas exhaust system is closed to stop the pressure control by the APC 224. Meanwhile, as the valve of the basic exhaust system is opened to exhaust the atmosphere of the conveyance space 203 by the TMP and the DP, the processing container 202 is maintained in a high-degree vacuum (ultra-high vacuum) state (for example, 10⁻⁵ Pa or less), and a pressure difference between the conveyance space 203 and the transfer chamber maintained at a high-degree vacuum (ultra-high vacuum) state (for example, 10⁻⁶ Pa or less) is reduced. In this state, the gate valve 205 is opened to unload the wafer 200 from the processing container 202 into the transfer chamber.

Next, in the substrate unloading/loading process S108, in a sequence like the above-mentioned substrate loading/placing process S102, the new wafer 200 on standby is loaded into the processing container 202, the wafer 200 is raised to the processing position in the processing space 201, and the inside of the processing space 201 becomes a predetermined processing temperature and processing pressure so that the film-forming process S104 becomes in a startable state. In addition, the film-forming process S104 and a processed number determination process S106 are performed on the new wafer 200 in the processing space 201.

(Substrate Unloading Process: S110)

In the substrate unloading process S110, the processed wafer 200 is extracted from the processing container 202 to be unloaded into the transfer chamber in a sequence like the above-mentioned substrate unloading/loading process S108. However, unlike the substrate unloading/loading process S108, in the substrate unloading process S110, loading of the new wafer 200 on standby into the processing container 202 is not performed such that no wafer 200 is present in the processing container 202.

When the substrate unloading process S110 is terminated, a cleaning process S112 is performed.

### (3) Cleaning Process

Next, as one process of the method of manufacturing the semiconductor device, the cleaning process S112 in which the cleaning processing in the processing container 202 of the substrate processing apparatus 100 is performed will be described in detail. In addition, even in the cleaning process S112, operations of the parts that constitute the substrate processing apparatus 100 are controlled by the controller 260.

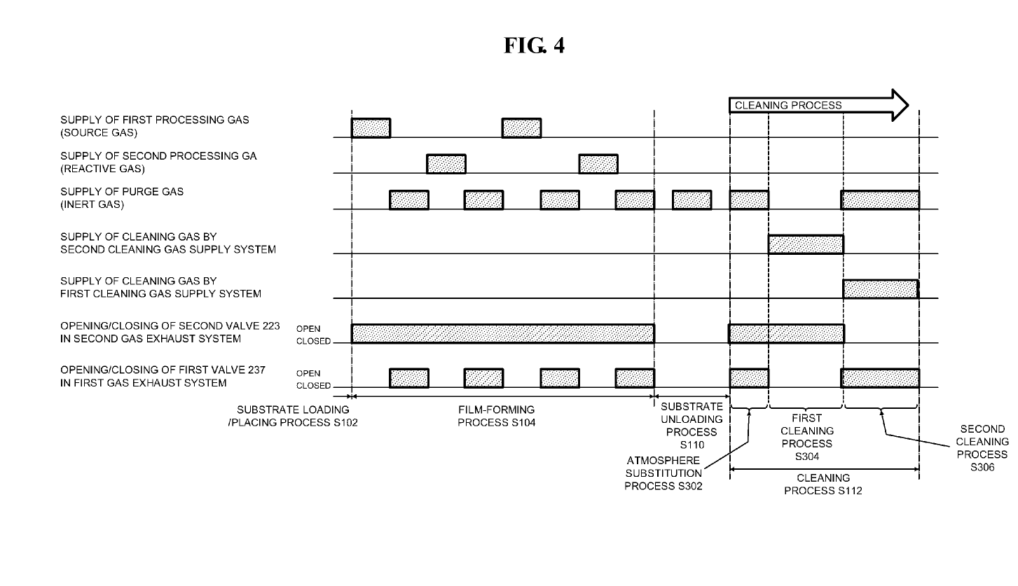

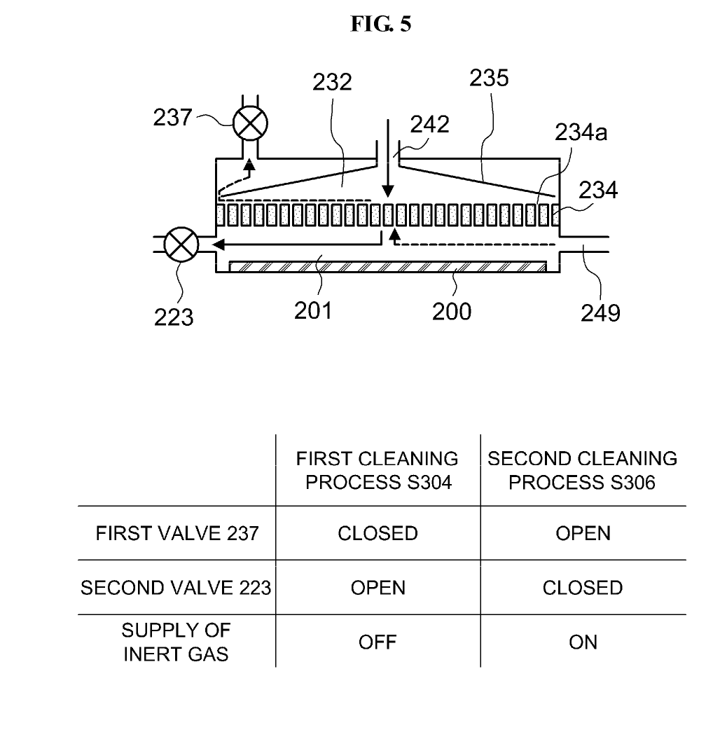

FIG. 4 is a time chart showing a detailed sequence of the cleaning process according to the embodiment. FIG. 5 is a view schematically showing a flow of the cleaning gas in the cleaning process according to the embodiment.

As shown in FIG. 4, the cleaning process S112 generally includes an atmosphere substitution process S302, a first cleaning process S304 and a second cleaning process S306.

(Atmosphere Substitution Process: S302)

In the atmosphere substitution process S302, the inert gas (N₂ gas) is supplied through the third gas supply pipe 245a, and the first valve 237 of the first gas exhaust system and the second valve 223 of the second gas exhaust system are each open. In addition, the inside of the shower head buffer chamber 232 and the inside of the processing space 201 are substituted with the inert gas atmosphere, and provided with cleaning conditions (a pressure, a temperature and so on) in the shower head buffer chamber 232 and the processing space 201. Accordingly, removal of delaminated matters or unexpected intrusion matters that may be generated by a pressure gradient or a temperature gradient from the inside of the shower head buffer chamber 232 or the inside of the processing space 201 is performed.

(First Cleaning Process: S304)

After the atmosphere substitution process S302 is performed for a sufficient time in substitution with the inert gas atmosphere in the shower head buffer chamber 232 and the processing space 201, the first cleaning process S304 is continuously performed. In the first cleaning process S304, the cleaning processing of the inside of the shower head buffer chamber 232 is mainly performed.

In the first cleaning process S304, the valve 248d of the second cleaning gas supply system is opened to supply the cleaning gas from the second cleaning gas supply source 248b into the shower head buffer chamber 232 through the third gas supply pipe 245a and the common gas supply pipe 242. In addition, in the first cleaning process S304, the second valve 223 of the second gas exhaust system is opened. Here, the first valve 237 of the first gas exhaust system is closed.

Accordingly, the cleaning gas supplied into the shower head buffer chamber 232 in the first cleaning process S304 is introduced into the processing space 201 through the through-hole 234a of the dispersion plate 234, and then, exhausted from the processing space 201 by the second gas exhaust system (see a solid arrow of FIG. 5).

Accordingly, in the first cleaning process S304, the cleaning processing of removing accumulated matters (reaction byproducts or the like) stuck to a lower surface of the gas guide 235 (a surface opposite to the dispersion plate 234), an upper surface of the dispersion plate 234 and so on using a flow of the above-mentioned cleaning gas may be performed.

The first cleaning process S304 is terminated after the cleaning processing is performed for a predetermined time. The predetermined time is not particularly limited as long as it is previously and appropriately set. In addition, when the cleaning processing starts and the predetermined time elapses, the first cleaning process S304 is terminated by closing the valve 248d and the second valve 223.

(Second Cleaning Process: S306)

After the above-mentioned first cleaning process S304, the second cleaning process S306 is performed. In the second cleaning process S306, the cleaning processing of the inside of the processing space 201 is mainly performed.

In the second cleaning process S306, the valve 249d of the first cleaning gas supply system 249 is opened to supply the cleaning gas from the first cleaning gas supply source 249b into the processing space 201 through the cleaning gas supply pipe 249a. In addition, in the second cleaning process S306, the first valve 237 of the first gas exhaust system is open. Here, the second valve 223 of the second gas exhaust system is closed.

In addition, in the second cleaning process S306, the cleaning gas is supplied into the processing space 201 by the first cleaning gas supply system 249, and the valve 245d of the inert gas supply system 245 is opened to supply the inert gas from the inert gas supply source 245b into the shower head buffer chamber 232 through the third gas supply pipe 245a and the common gas supply pipe 242. That is, in the second cleaning process S306, supply of the cleaning gas into the processing space 201 by the first cleaning gas supply system 249 and supply of the inert gas into the shower head buffer chamber 232 by the inert gas supply system 245 are performed in parallel.

Here, “the supply is performed in parallel” means “the supply of the inert gas is performed such that the cleaning gas introduced into the shower head buffer chamber 232 from the processing space 201 does not intrude into the gas guide 235 or the common gas supply pipe 242.” Accordingly, timing between supply of the cleaning gas by the first cleaning gas supply system 249 and supply of the inert gas by the inert gas supply system 245 specifically starts the supply of the inert gas before the supply of the cleaning gas, and then, starts the supply of the cleaning gas or starts the supply of the inert gas concurrently with starting of the supply of the cleaning gas. In addition, an inner side of the gas guide 235 is a surface inside the gas guide 235 and opposite to the dispersion plate 234.

Accordingly, the cleaning gas supplied into the processing space 201 in the second cleaning process S306 is introduced into the shower head buffer chamber 232 through the through-hole 234a of the dispersion plate 234. However, a gas curtain is formed at an inner portion of the gas guide 235 by the supply of the inert gas in the shower head buffer chamber 232. For this reason, the cleaning gas introduced into the shower head buffer chamber 232 is not introduced into the inner portion of the gas guide 235 or the common gas supply pipe 242 but exhausted from the inside of the shower head buffer chamber 232 by the first gas exhaust system (see a broken arrow of FIG. 5).

Accordingly, in the second cleaning process S306, the cleaning processing of removing the accumulated matters (reaction byproducts or the like) stuck into the processing space 201 may be performed mainly using the flow of the above-mentioned cleaning gas. In addition, since the gas curtain by the inert gas is formed at an inner portion of the gas guide 235, in the gas guide 235 cleaned in the first cleaning process S304, the delaminated matters (reaction byproducts or the like) from the processing space 201 can be prevented from being stuck to a surface of the gas guide 235 opposite to the dispersion plate 234, and over-etching of the surface of the gas guide 235 opposite to the dispersion plate 234 can be prevented.

In addition, in the second cleaning process S306, after the cleaning processing of the inside of the shower head buffer chamber 232 is performed in the first cleaning process S304, the cleaning processing of the inside of the processing space 201 is performed. Accordingly, even when the delaminated matters generated upon cleaning of the inside of the shower head buffer chamber 232 in the first cleaning process S304 are stuck to a wall in the processing space 201, since the delaminated matters can be removed again in the second cleaning process S306, cleanliness in the processing space 201 can be maintained at a higher level.

The second cleaning process S306 is terminated after the above-mentioned cleaning processing is performed for a predetermined time. The predetermined time is not particularly limited as long as the predetermined time is appropriately set like the first cleaning process S304, but the predetermined time may be set, for example, like the predetermined time of the first cleaning process S304. In addition, when the cleaning processing starts and the predetermined time elapses, the valves 249d and 245d and the first valve 237 are closed to stop the second cleaning process S306.

### (4) Effects According to Embodiment

According to the embodiment, one or a plurality of effects will be described as follows.

(a) According to the embodiment, in the cleaning process S112, the cleaning processing using the cleaning gas is performed in the shower head buffer chamber 232 and the processing space 201. Accordingly, unlike the case in which the cleaning processing is manually performed by an operator upon maintenance of the apparatus, the accumulated matters (reaction byproducts or the like) stuck to the inside of the shower head buffer chamber 232 and the inside of the processing space 201 can be removed without a decrease in operating efficiency of the apparatus as possible.

In addition, according to the embodiment, as the second cleaning gas supply system and the first cleaning gas supply system 249 are provided, the cleaning gas can be separately and directly supplied into the shower head buffer chamber 232 and the processing space 201. Accordingly, since the cleaning gas can arrive at the inside of the shower head buffer chamber 232 and the inside of the processing space 201 before deactivation, the cleaning processing in both of the insides can be sufficiently performed.

In addition, according to the embodiment, as the supply of the cleaning gas into the processing space 201 and the supply of the inert gas into the shower head buffer chamber 232 are performed in parallel, the gas curtain by the inert gas is formed at the inner portion of the gas guide 235. Accordingly, the inner portion of the gas guide 235 or the inside of the common gas supply pipe 242 included in the shower head 230 is not over-etched. In addition, when the cleaning gas which removed the stuck matter in the processing space 201 flows from the processing space 201 toward the showerhead, the gas curtain prevents the cleaning gas from being pass through the inside of the gas guide 235. That is, the inner portion of the gas guide 235 is not contaminated with the used cleaning gas.

That is, according to the embodiment, the cleaning processing can be sufficiently and appropriately performed in the shower head 230 and the processing space 201.

(b) In addition, according to the embodiment, in the cleaning process S112, the first cleaning process S304 and the second cleaning process S306 are performed. Accordingly, the cleaning processing is sufficiently performed in the shower head 230 and the processing space 201 when the cleaning process S112 is terminated, and even in this case, the inner portion of the gas guide 235 included in the shower head 230 is not over-etched or contaminated. That is, in the cleaning process S112, as the first cleaning process S304 of flowing the cleaning gas from the shower head 230 toward the processing space 201 and the second cleaning process S306 of reversely flowing the cleaning gas from the processing space 201 toward the shower head 230 are performed, the cleaning processing of the inside of the shower head 230 and the inside of the processing space 201 can be sufficiently and appropriately performed, and the cleaning processing with respect to each of the insides can be efficiently performed. In particular, as described in the embodiment, when the second cleaning process S306 is performed after the first cleaning process S304, cleanliness in the processing space 201 can be maintained at a higher level.

(c) In addition, according to the embodiment, the control member is configured to control the gas exhaust system of the cleaning process S112 to close the first valve 237 of the first gas exhaust system and open the second valve 223 of the second gas exhaust system in the first cleaning process S304, and open the first valve 237 of the first gas exhaust system and close the second valve 223 of the second gas exhaust system in the second cleaning process S306. Accordingly, a flow of the cleaning gas passing through the processing space 201 from the shower head buffer chamber 232 and exhausted by the second gas exhaust system in the first cleaning process S304 and a flow of the cleaning gas flowing through the shower head buffer chamber 232 from the processing space 201 and exhausted by the first gas exhaust system in the second cleaning process S306 can be securely formed. That is, as the flows of the cleaning gases are securely formed as described above, the cleaning processing of the inside of the shower head 230 and the inside of the processing space 201 can be sufficiently and appropriately performed.

### Second Embodiment of the Invention

Next, a second embodiment of the present invention will be described. Here, the second embodiment will be described focusing on differences from the above-mentioned first embodiment, and the other descriptions will be omitted.

The second embodiment of the present invention is distinguished from the above-mentioned first embodiment in the first cleaning process S304 of the cleaning process S112.

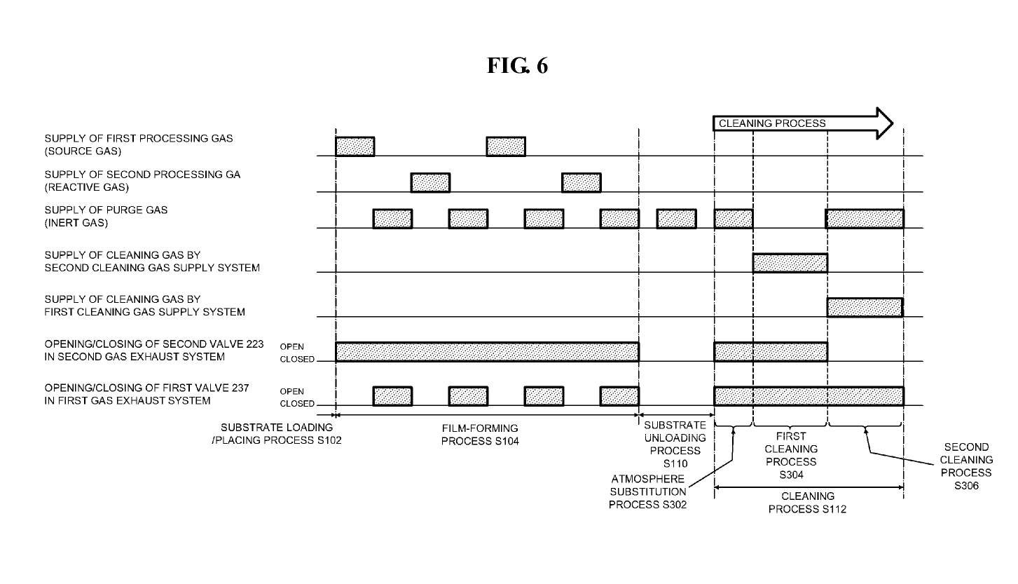

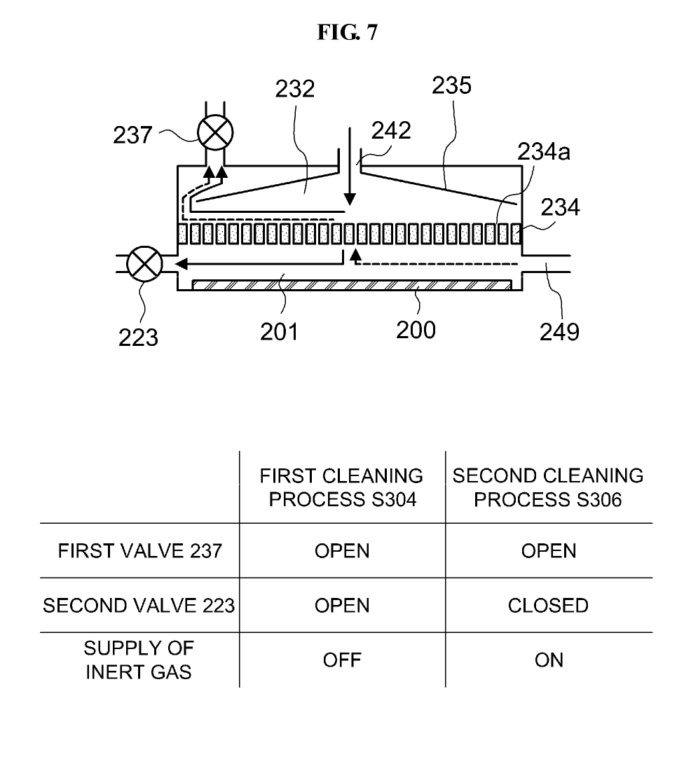

FIG. 6 is a time chart showing a detailed sequence of a cleaning process according to the embodiment. FIG. 7 is a view schematically showing a flow of a cleaning gas in the cleaning process of the embodiment.

(First Cleaning Process: S304)

In the first cleaning process S304 of the embodiment, the second valve 223 of the second gas exhaust system is open and the first valve 237 of the first gas exhaust system is open (closed in the first embodiment). As a result, the atmosphere in the shower head buffer chamber 232 is exhausted by the second gas exhaust system through the through-holes 234a of the dispersion plate 234 and the processing space 201, and also exhausted by the first gas exhaust system in communication with the shower head buffer chamber 232. However, since the flow of the gas formed by the second gas exhaust system is provided via the through-holes 234a of the dispersion plate 234, conductance thereof is smaller than the flow of the gas formed by the first gas exhaust system. For this reason, the atmosphere in the shower head buffer chamber 232 is mainly exhausted by the first gas exhaust system, and the other is exhausted by the second gas exhaust system (see a solid arrow of FIG. 7).

In addition, while the cleaning processing of the inside of the shower head buffer chamber 232 is mainly performed in the first cleaning process S304, in this case, when a hole diameter of the through-hole 234a of the dispersion plate 234 is small, the delaminated matters (reaction byproducts or the like) by the cleaning processing may be clogged in the through-holes 234a. For this reason, in the first cleaning process S304 of the embodiment, the first valve 237 is also open together with the second valve 223. Accordingly, the delaminated matters that may be generated by the cleaning processing of the inside of the shower head buffer chamber 232 flows toward the first gas exhaust system having high conductance to be exhausted from the shower head buffer chamber 232 by the first gas exhaust system as it is without passing through the through-holes 234a. That is, the delaminated matters that may be generated in the shower head buffer chamber 232 can be prevented from being clogged in the through-holes 234a using a difference in conductance between the flow of the gas formed by the first gas exhaust system and the flow of the gas formed by the second gas exhaust system. In addition, the cleaning gas flowing through the through-holes 234a of the dispersion plate 234 toward the processing space 201, without flowing toward the first gas exhaust system, cleans sidewalls of the through-holes 234a, and then is exhausted through the exhaust hole 221 connected to the second gas exhaust system via the processing space 201 and the exhaust buffer chamber 209.

### Effects According to Embodiment

According to the embodiment, in addition to the one or the plurality of effects of the above-mentioned first embodiment, the following effects will be provided.

(d) According to the embodiment, the control member is configured to control the gas exhaust system of the cleaning process S112 to open the first valve 237 of the first gas exhaust system and the second valve 223 of the second gas exhaust system in the first cleaning process S304, and open the first valve 237 of the first gas exhaust system and close the second valve 223 of the second gas exhaust system in the second cleaning process S306. Accordingly, a flow of the cleaning gas mainly exhausted by the first gas exhaust system and a flow of the remaining cleaning gas exhausted by the second gas exhaust system can be securely formed by a difference in conductance between the flow of the gas formed by the first gas exhaust system and the flow of the gas formed by the second gas exhaust system in the first cleaning process S304. That is, as the flows of the cleaning gases are securely formed as described above, even when the delaminated matters (reaction byproducts or the like) are generated in the cleaning processing of the inside of the shower head buffer chamber 232, the delaminated matters can be prevented from being clogged in the through-holes 234a of the dispersion plate 234.

### Third Embodiment of the Invention

Next, a third embodiment of the present invention will be described. Here, the third embodiment will also be described focusing on differences from the above-mentioned first embodiment, and the other descriptions will be omitted.

The third embodiment of the present invention is distinguished from the first embodiment in the second cleaning process S306 of the cleaning process S112.

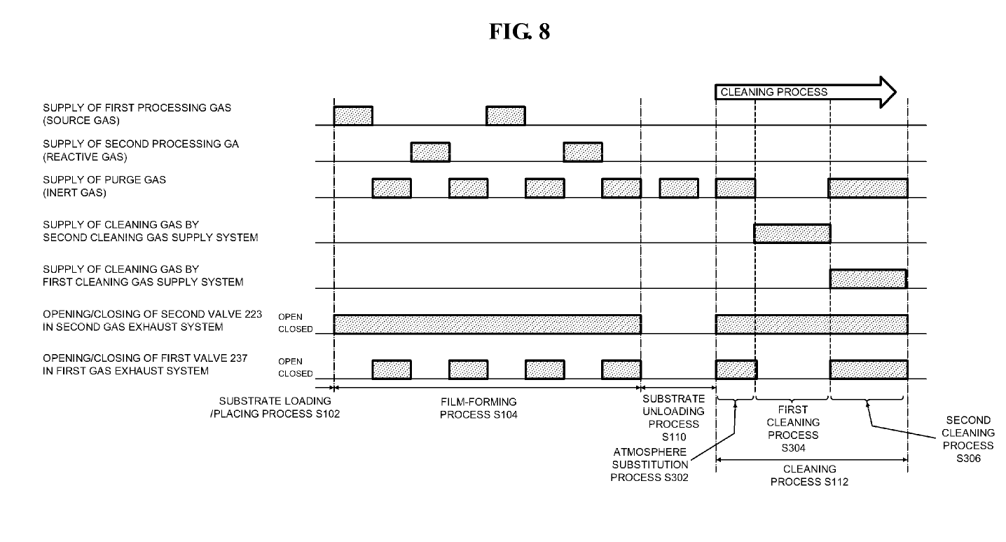

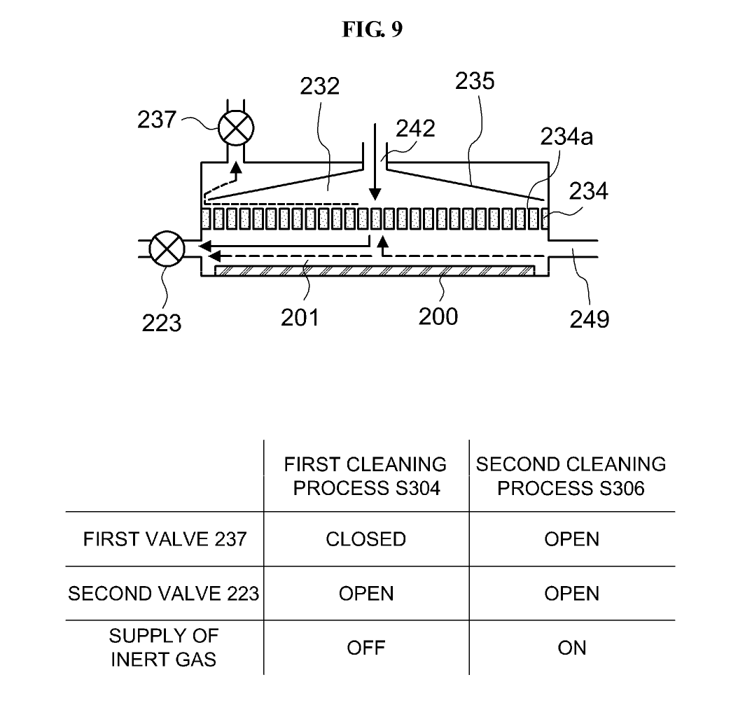

FIG. 8 is a time chart showing a detailed sequence of a cleaning process according to the embodiment. FIG. 9 is a view schematically showing a flow of a cleaning gas in the cleaning process according to the embodiment.

(Second Cleaning Process: S306)

In the second cleaning process S306 of the embodiment, the first valve 237 of the first gas exhaust system is open, and the second valve 223 of the second gas exhaust system is also open (closed in the first embodiment). As a result, the atmosphere in the processing space 201 is exhausted by the first gas exhaust system through the through-holes 234a of the dispersion plate 234 and the shower head buffer chamber 232, and also exhausted by the second gas exhaust system in communication with the processing space 201 via the exhaust buffer chamber 209. However, since the flow of the gas formed by the first gas exhaust system is provided via the through-holes 234a of the dispersion plate 234, conductance thereof is smaller than the flow of the gas formed by the second gas exhaust system. For this reason, the atmosphere in the processing space 201 is mainly exhausted by the second gas exhaust system, and the remaining atmosphere is exhausted by the first gas exhaust system (see a broken arrow of FIG. 9).

In addition, while the cleaning processing of the inside of the processing space 201 is mainly performed in the second cleaning process S306, in this case, when a hole diameter of the through-hole 234a of the dispersion plate 234 is small, the delaminated matters (reaction byproducts or the like) by the cleaning processing may be clogged in the through-holes 234a. Therefore, in the embodiment, the control member is configured to open the second valve 223 together with the first valve 237 in the second cleaning process S306. Accordingly, the delaminated matters that may be generated in the cleaning processing of the inside of the processing space 201 flows toward the second gas exhaust system having high conductance to be exhausted from the processing space 201 by the second gas exhaust system as it is without passing through the through-holes 234a. That is, the delaminated matters that may be generated in the processing space 201 can be prevented from being clogged in the through-holes 234a using a difference in conductance between the flow of the gas formed by the first gas exhaust system and the flow of the gas formed by the second gas exhaust system. In addition, the cleaning gas flowing through the through-hole 234a of the dispersion plate 234 toward the shower head buffer chamber 232, without flowing toward the second gas exhaust system, cleans the sidewalls of the through-holes 234a, and then, exhausted by the first gas exhaust system via the shower head buffer chamber 232.

Here, while the cleaning gas flowing in the shower head buffer chamber 232 does not have delaminated matters having a large size sufficient to clog the through-holes 234a, the cleaning gas may be contaminated by the cleaning processing of the inside of the processing space 201. However, since the gas curtain by the inert gas is formed at the inner portion of the gas guide 235 and the inside of the common gas supply pipe 242 in the shower head buffer chamber 232, even when the contaminated cleaning gas flows in the shower head buffer chamber 232, no cleaning gas sticks to a lower surface of the gas guide 235 (a surface opposite to the dispersion plate 234) or the common gas supply pipe 242.

### Effects According to Embodiment

According to the embodiment, in addition to the one or the plurality of effects of the above-mentioned first embodiment, the following effects will be provided.

(e) According to the embodiment, the control member is configured to control the gas exhaust system in the cleaning process S112 to close the first valve 237 of the first gas exhaust system and open the second valve 223 of the second gas exhaust system in the first cleaning process S304, and open the first valve 237 of the first gas exhaust system and the second valve 223 of the second gas exhaust system in the second cleaning process S306. Accordingly, the flow of the cleaning gas mainly exhausted by the second gas exhaust system and the flow of the remaining cleaning gas exhausted by the first gas exhaust system can be securely formed by a difference in conductance between the flow of the gas formed by the first gas exhaust system and the flow of the gas formed by the second gas exhaust system in the second cleaning process S306. That is, as the flows of the cleaning gases are securely formed as described above, even when the delaminated matters (reaction byproducts or the like) are generated by the cleaning processing of the inside of the processing space 201, the delaminated matters can be prevented from being clogged in the through-holes 234a of the dispersion plate 234.

### Fourth Embodiment of the Invention

Next, a fourth embodiment of the present invention will be described. However, the fourth embodiment will also be described focusing on differences from the above-mentioned first, second or third embodiment, and the other descriptions will be omitted.

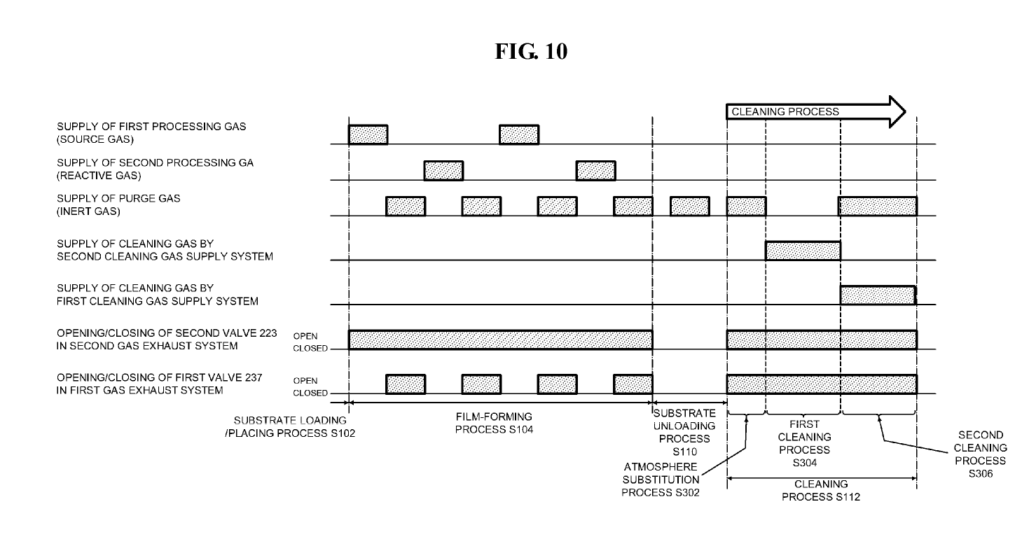

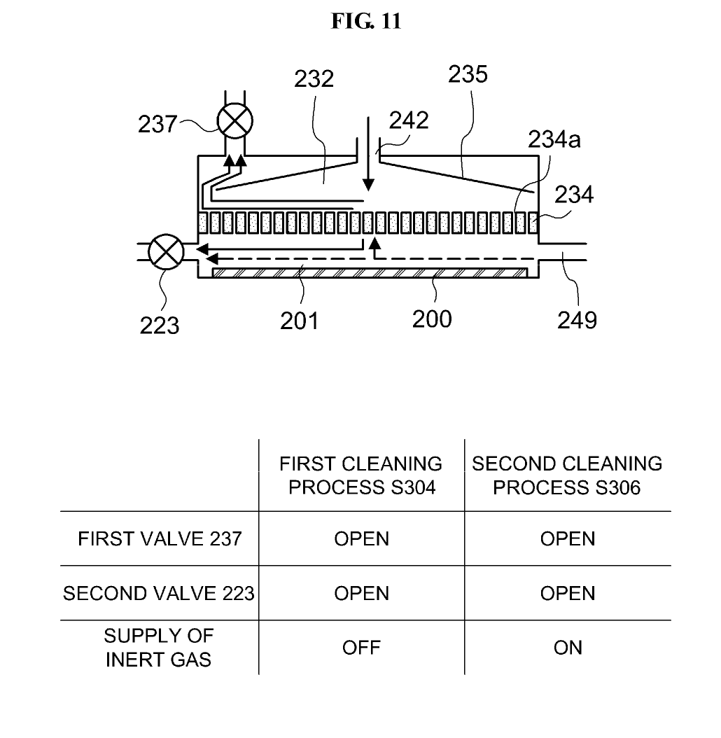

FIG. 10 is a time chart showing a detailed sequence of a cleaning process according to the embodiment. FIG. 11 is a view schematically showing a flow of a cleaning gas in the cleaning process according to the embodiment.

(Cleaning Process: S112)

In the cleaning process S112 of the embodiment, after the atmosphere substitution process S302 is terminated, the first cleaning process S304 described in the second embodiment and the second cleaning process S306 described in the third embodiment are combined and performed. That is, the control member is configured to open the second valve 223 of the second gas exhaust system and also open the first valve 237 of the first gas exhaust system in the first cleaning process S304. In addition, the control member is configured to open the first valve 237 of the first gas exhaust system and also open the second valve 223 of the second gas exhaust system in the second cleaning process S306.

### Effects According to Embodiment

According to the embodiment, in addition to the one or the plurality of effects of the above-mentioned first, second or third embodiment, the following effects will be provided.

(f) According to the embodiment, the delaminated matters (reaction byproducts or the like) generated in the cleaning processing can be prevented from being clogged in the through-holes 234a of the dispersion plate 234 even in the first cleaning process S304 and the second cleaning process S306 using a difference in conductance between the flow of the gas formed by the first gas exhaust system and the flow of the gas formed by the second gas exhaust system.

### Fifth Embodiment of the Invention

Next, a fifth embodiment of the present invention will be described. However, the fifth embodiment will also be described focusing on differences from the above-mentioned embodiments, and the other descriptions will be omitted.

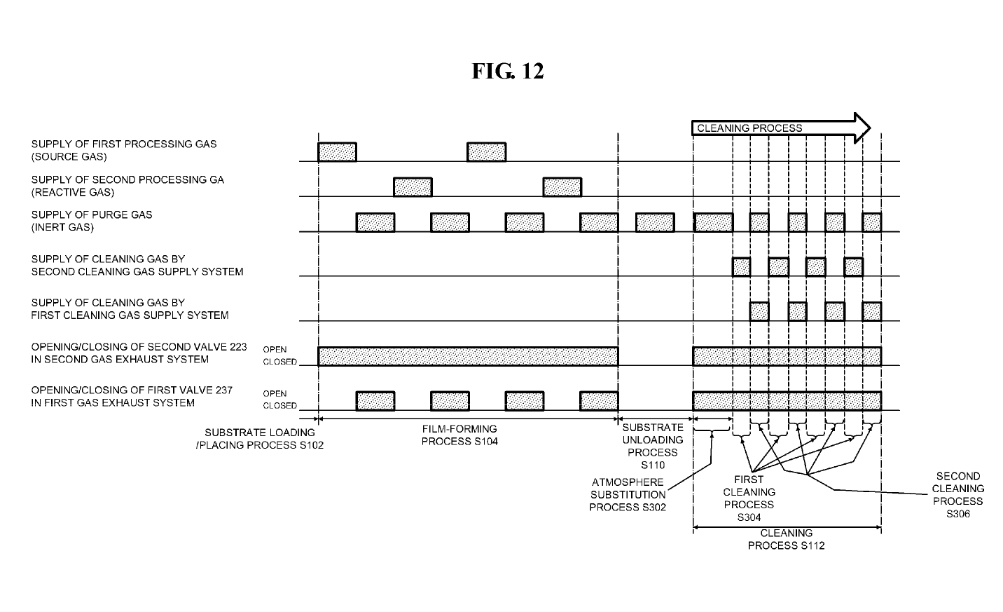

FIG. 12 is a time chart showing a detailed sequence of a cleaning process according to the embodiment.

(Cleaning Process: S112)

In the cleaning process S112 of the embodiment, after the atmosphere substitution process S302 is terminated, the first cleaning process S304 and the second cleaning process S306 are alternately repeated. That is, each of the first cleaning process S304 and the second cleaning process S306 is divided by a plurality of number of times, and sets of the first cleaning processes and the second cleaning processes are alternately performed.

Here, each processing time of the first cleaning process S304 may be a time obtained by uniformly dividing a total processing time (a predetermined time) of the first cleaning process S304 using a cycle repetition number. That is, when the total processing time (the predetermined time) of the first cleaning process S304 is T, each processing time is “T/cycle repetition number.” This is similar to the second cleaning process S306. In addition, each processing time may also be similarly set with respect to a relation between the first cleaning process S304 and the second cleaning process S306.

The flow of the cleaning gas of each of the first cleaning process S304 and the second cleaning process S306 may be any one of the above-mentioned first embodiment to fourth embodiment.

As described above, when each processing time is reduced as each of the first cleaning process S304 and the second cleaning process S306 is divided by a plurality of number of times and alternately repeated, an amount of the delaminated matters (reaction byproducts or the like) per each time is reduced in comparison with each of the above-mentioned embodiments. When the amount of the delaminated matters is reduced, probability of clogging in the through-holes 234a of the dispersion plate 234 can be reduced.

In addition, in the embodiment, like the above-mentioned embodiments, while the gas curtain with respect to the inner portion of the gas guide 235 is formed by the supply of the inert gas only in the second cleaning process S306 and the supply of the inert gas is stopped in the first cleaning process S304, the embodiment is not limited thereto but the supply of the inert gas may be performed even in the first cleaning process S304. In this case, since the inert gas continuously flows in the shower head buffer chamber 232, the lower surface of the gas guide 235 can be securely prevented from over-etching, contamination, or the like, with respect to high speed supply switching of the cleaning gas like the embodiment. In addition, intrusion of the delaminated matters into the common gas supply pipe 242 can be securely prevented.

In addition, when the first cleaning process S304 and the second cleaning process S306 are alternately repeated like the embodiment, a distance between a front end of the gas guide 235 and the dispersion plate 234 may be small. When the distance between the front end of the gas guide 235 and the dispersion plate 234 is small, a volume (amount) of the gas staying around the front end of the gas guide 235 is reduced in comparison with the case in which the distance is large, and the gas exhaust can be rapidly performed. Accordingly, even when the first cleaning process S304 and the second cleaning process S306 are alternately repeated, the respective processes can be changed without time consumption, and as a result, the entire cleaning process S112 can be efficiently performed.

### Effects of Embodiment

According to the embodiment, in addition to the one or the plurality of effects of the above-mentioned first, second, third or fourth embodiment, the following effects will be provided.

(g) According to the embodiment, as the first cleaning process S304 and the second cleaning process S306 are divided by a plurality of number of times to be alternately repeated in the cleaning process S112, each processing time can be reduced. Accordingly, in each of the first cleaning process S304 and the second cleaning process S306, the amount of the delaminated matters (reaction byproducts or the like) per each time can be reduced, and thus, probability of clogging in the through-holes 234a of the dispersion plate 234 can be further reduced.

### Sixth Embodiment of the Invention

Next, a sixth embodiment of the present invention will be described. However, the sixth embodiment will also be described focusing on differences from the fifth embodiment, and the other descriptions will be omitted.

(Cleaning Process: S112)

Even in the cleaning process S112 of the embodiment, like the above-mentioned fifth embodiment, the first cleaning process S304 and the second cleaning process S306 are divided by a plurality of number of times to be alternately repeated. However, in the fifth embodiment, each processing time of each of the processes S304 and S306 is a time obtained by uniformly dividing the total processing time (the predetermined time) using a cycle repetition number. In the embodiment, unlike the fifth embodiment, the processing time of each time may be set as a variable time of each time, other than an equal time.

Specifically, for example, the processing time of each time can be gradually varied such that the processing time is reduced at an initial time of the cleaning and the processing time is increased at a final time of the cleaning in each of the first cleaning process S304 and the second cleaning process S306. As a result, in the initial time of the cleaning in which the delaminated matters (reaction byproducts or the like) are likely to be generated, the cleaning processing of each of the inside of the shower head 230 and the inside of the processing space 201 can be sufficiently and appropriately performed while reducing the processing time per each time and reducing probability of clogging in the through-holes 234a of the dispersion plate 234. However, the embodiment is not limited to the type but the processing time of each time may be gradually varied such that the processing time of the initial time of the cleaning is increased and the processing time of the final time of the cleaning is reduced in each of the first cleaning process S304 and the second cleaning process S306.

In addition, in the embodiment, a method of varying the processing time of each time may be previously appropriately set in consideration of a processing condition, a kind of gas or the like used in the film-forming processing.

### Effects of Embodiment

According to the embodiment, in addition to the one or the plurality of effects of the above-mentioned fifth embodiment, the following effects will be provided.

(h) According to the embodiment, as the processing time of each time is set to be variable when the first cleaning process S304 and the second cleaning process S306 are divided by a plurality of number of times to be alternately repeated in the cleaning process S112, a repeated cycle according to the processing condition, the kind of gas or the like used in the film-forming processing can be realized. That is, the cleaning processing of each of the inside of the shower head 230 and the inside of the processing space 201 can be sufficiently and appropriately performed while securing versatility of the processing condition, the kind of gas or the like used in the film-forming processing.

### Another Embodiment of the Invention

Hereinabove, while the embodiments of the present invention have been described in detail, the present invention is not limited to the embodiments but may be variously modified without departing the spirit of the present invention.

For example, while the case in which the first cleaning process S304 and the second cleaning process S306 are performed for the same period of time in the above-mentioned embodiments has been exemplified, the present invention is not limited thereto. That is, the processing times of the first cleaning process S304 and the second cleaning process S306 may be different from each other according to the processing condition, the kind of gas or the like used in the film-forming processing. In addition, for example, in the above-mentioned embodiments, while the case in which the second cleaning process S306 is performed after the first cleaning process S304 is performed has been exemplified, the sequence thereof may be reversed.

In addition, for example, in the above-mentioned embodiments, while the case in which the SiN film is formed on the wafer 200 by alternately supplying the Si₂Cl₆ gas serving as the source gas (the first processing gas) and the NH₃ gas serving as the reactive gas (the second processing gas) in the film-forming processing performed by the substrate processing apparatus 100 has been exemplified, the present invention is not limited thereto. That is, the processing gas used in the film-forming processing is not limited to Si₂Cl₆ gas, NH₃ gas or the like, but another kind of thin film may be formed using another kind of gas. In addition, even when three or more types of processing gases are used, the present invention may be applied as long as the processing gases are alternately supplied to perform the film-forming processing.

In addition, for example, in the above-mentioned embodiments, while the film-forming processing is exemplified as the processing performed by the substrate processing apparatus 100, the present invention is not limited thereto. That is, in addition to the film-forming processing, the processing may be processing of forming an oxide film or a nitride film, or processing of forming a film including a metal. In addition, specific contents of the substrate processing is unmentioned and may be applied to another substrate processing such as annealing processing, oxidation processing, nitration processing, diffusion processing, lithography processing, or the like, as well as the film-forming processing. In addition, the present invention may be applied to another substrate processing apparatus such as an annealing processing apparatus, an oxidation processing apparatus, a nitration processing apparatus, an exposure apparatus, an application apparatus, a drying apparatus, a heating apparatus, a processing apparatus using plasma and so on. In addition, these apparatuses may be combined in the present invention. In addition, a part of the configuration of the embodiment may be substituted with a configuration of another embodiment, or a configuration of another embodiment may be added to a configuration of a certain embodiment. In addition, other configurations may be added to, deleted from, or substituted with a part of the configuration of each of the embodiments.

According to the present invention, even when the gas supply is performed via the shower head, the cleaning processing with respect to each of the inside of the shower head and the inside of the processing space can be sufficiently and appropriately performed.

### Exemplary Modes of the Invention

Hereinafter, preferred embodiments of the present invention are supplementarily noted.

<Supplementary Note 1>

According to an aspect of the present invention, there is provided a substrate processing apparatus including:

a processing space for processing a substrate;

a shower head buffer chamber disposed adjacent to the processing space with a dispersion plate having through-holes therebetween;

an inert gas supply system configured to supply an inert gas into the shower head buffer chamber to form a gas curtain in the shower head buffer chamber;

a first cleaning gas supply system configured to supply a cleaning gas into the processing space;

a control member configured to control the inert gas supply system and the first cleaning gas supply system to concurrently supply the cleaning gas into the processing space and the inert gas into the shower head buffer chamber.

<Supplementary Note 2>

In the substrate processing apparatus of Supplementary note 1, preferably, further includes a second cleaning gas supply system configured to supply the cleaning gas into the shower head buffer chamber, and the control member is configured to control the inert gas supply system, the first cleaning gas supply system and the second cleaning gas supply system to perform: (a) supplying the cleaning gas into the shower head buffer chamber by the second cleaning gas supply system and (b) supplying the cleaning gas into the processing space by the first cleaning gas supply system and the inert gas into the shower head buffer chamber by the inert gas supply system.

<Supplementary Note 3>

In the substrate processing apparatus of Supplementary note 2, preferably, further includes: a first gas exhaust system configured to exhaust a gas in the shower head buffer chamber; and a second gas exhaust system configured to exhaust a gas in the processing space, and the control member is configured to control the inert gas supply system, the first cleaning gas supply system, the second cleaning gas supply system, the first gas exhaust system and the second gas exhaust system to close a first valve of the first gas exhaust system and open a second valve of the second gas exhaust system in (a), and open the first valve and close the second valve in (b).

<Supplementary Note 4>

In the substrate processing apparatus of any one of Supplementary notes 2 and 3, preferably, the control member is configured to control the inert gas supply system, the first cleaning gas supply system and the second cleaning gas supply system to repeat (a) and (b) alternately.

<Supplementary Note 5>

According to another aspect of the present invention, there is provided a substrate processing apparatus including:

a processing space for processing a substrate placed on a substrate placing surface;

a shower head buffer chamber communicating with the processing space through through-holes of a dispersion plate disposed above the substrate placing surface, the shower head buffer chamber including a gas guide configured to guide a gas supplied from above the dispersion plate toward the processing space;

an inert gas supply system configured to supply an inert gas to form a gas curtain in the shower head buffer chamber between the gas guide and the dispersion plate;

a first cleaning gas supply system configured to supply a cleaning gas into the processing space;

a second cleaning gas supply system configured to supply the cleaning gas into the shower head buffer chamber;

a first gas exhaust system configured to exhaust a gas in the shower head buffer chamber;

a second gas exhaust system configured to exhaust a gas in the processing space; and

a control member configured to control the first cleaning gas supply system, the second cleaning gas supply system, the inert gas supply system, the first gas exhaust system and the second gas exhaust system to concurrently supply at least the cleaning gas into the processing space and the inert gas into the shower head buffer chamber.

<Supplementary Note 6>

In the substrate processing apparatus of Supplementary note 5, preferably, the control member is configured to control the first cleaning gas supply system, the second cleaning gas supply system, the inert gas supply system, the first gas exhaust system and the second gas exhaust system to perform: (a) supplying the cleaning gas into the shower head buffer chamber by the second cleaning gas supply system and (b) supplying the cleaning gas into the processing space by the first cleaning gas supply system and the inert gas into the shower head buffer chamber by the inert gas supply system.

<Supplementary Note 7>

In the substrate processing apparatus of Supplementary note 6, preferably, the control member is configured to control the first cleaning gas supply system, the second cleaning gas supply system, the inert gas supply system, the first gas exhaust system and the second gas exhaust system to close a first valve of the first gas exhaust system and open a second valve of the second gas exhaust system in (a), and open the first valve and close the second valve in (b).

<Supplementary Note 8>

In the substrate processing apparatus of Supplementary note 6, preferably, the control member is configured to control the first cleaning gas supply system, the second cleaning gas supply system, the inert gas supply system, the first gas exhaust system and the second gas exhaust system to open a first valve of the first gas exhaust system and a second valve of the second gas exhaust system in (a), and open the first valve and close the second valve in (b).

<Supplementary Note 9>

In the substrate processing apparatus of Supplementary note 6, preferably, the control member is configured to control the first cleaning gas supply system, the second cleaning gas supply system, the inert gas supply system, the first gas exhaust system and the second gas exhaust system to open a first valve of the first gas exhaust system and a second valve of the second gas exhaust system in (a), and open the first valve and the second valve in (b).

<Supplementary Note 10>

In the substrate processing apparatus of Supplementary note 6, preferably, the control member is configured to control the first cleaning gas supply system, the second cleaning gas supply system, the inert gas supply system, the first gas exhaust system and the second gas exhaust system to close a first valve of the first gas exhaust system and open a second valve of the second gas exhaust system in (a), and open the first valve and the second valve in (b).

<Supplementary Note 11>

In the substrate processing apparatus of any one of Supplementary notes 6 through 10, preferably, the control member is configured to control the first cleaning gas supply system, the second cleaning gas supply system, the inert gas supply system, the first gas exhaust system and the second gas exhaust system to repeat (a) and (b) alternately.

<Supplementary Note 12>

According to still another aspect of the present invention, there is provided a method of manufacturing a semiconductor device including:

(a) loading a substrate into a processing space and processing the substrate;

(b) unloading the substrate from the processing space; and

(c) concurrently supplying a cleaning gas into the processing space and supplying an inert gas into a shower head buffer chamber disposed adjacent to the processing space with a dispersion plate having through-holes therebetween.

<Supplementary Note 13>

According to still another aspect of the present invention, there is provided a method of manufacturing a semiconductor device including:

(a) loading a substrate into a processing space;

(b) processing the substrate by supplying a processing gas into a shower head buffer chamber communicating with the processing space through through-holes of a dispersion plate disposed above a substrate placing surface in the processing space and guiding the processing gas toward the processing space by a gas guide in the shower head buffer chamber configured to guide the processing gas supplied from above the dispersion plate to reach the processing space via the through-holes of the dispersion plate;

(c) unloading the substrate from the processing space;

(d) supplying a cleaning gas into the shower head buffer chamber by a second cleaning gas supply system connected to the shower head buffer chamber above the dispersion plate; and

(e) supplying the cleaning gas into the processing space by a first cleaning gas supply system connected to the processing space and an inert gas into the shower head buffer chamber by an inert gas supply system connected to the shower head buffer chamber above the dispersion plate.

<Supplementary Note 14>

According to still another aspect of the present invention, there is provided a program for causing a computer to perform:

(a) loading a substrate into a processing space;

(b) processing the substrate by supplying a processing gas into a shower head buffer chamber communicating with the processing space through through-holes of a dispersion plate disposed above a substrate placing surface in the processing space and guiding the processing gas toward the processing space by a gas guide in the shower head buffer chamber configured to guide the processing gas supplied from above the dispersion plate to reach the processing space via the through-holes of the dispersion plate;

(c) unloading the substrate from the processing space;

(d) supplying a cleaning gas into the shower head buffer chamber by a second cleaning gas supply system connected to the shower head buffer chamber above the dispersion plate; and

(e) supplying the cleaning gas into the processing space by a first cleaning gas supply system connected to the processing space and an inert gas into the shower head buffer chamber by an inert gas supply system connected to the shower head buffer chamber above the dispersion plate.

<Supplementary Note 15>

According to still another aspect of the present invention, there is provided a non-transitory computer-readable recording medium storing a program causing a computer to perform:

(a) loading a substrate into a processing space;

(b) processing the substrate by supplying a processing gas into a shower head buffer chamber communicating with the processing space through through-holes of a dispersion plate disposed above a substrate placing surface in the processing space and guiding the processing gas toward the processing space by a gas guide in the shower head buffer chamber configured to guide the processing gas supplied from above the dispersion plate to reach the processing space via the through-holes of the dispersion plate;

(c) unloading the substrate from the processing space;

(d) supplying a cleaning gas into the shower head buffer chamber by a second cleaning gas supply system connected to the shower head buffer chamber above the dispersion plate; and

(e) supplying the cleaning gas into the processing space by a first cleaning gas supply system connected to the processing space and an inert gas into the shower head buffer chamber by an inert gas supply system connected to the shower head buffer chamber above the dispersion plate.

What is claims is:

1. A substrate processing apparatus comprising:
a processing space for processing a substrate;
a shower head buffer chamber disposed adjacent to the processing space with a dispersion plate having through-holes therebetween;
an inert gas supply system configured to supply an inert gas into the shower head buffer chamber to form a gas curtain in the shower head buffer chamber;
a first cleaning gas supply system configured to supply a cleaning gas into the processing space; and
a control member configured to control the inert gas supply system and the first cleaning gas supply system to concurrently supply the cleaning gas into the processing space and the inert gas into the shower head buffer chamber.

2. The substrate processing apparatus of claim 1, further comprising:
a gas inlet hole disposed at a ceiling of the shower head buffer chamber and configured to supply the inert gas; and
a gas guide having a diameter increasing from the gas inlet hole toward the dispersion plate, and wherein the gas curtain is formed between the gas guide and the dispersion plate.

3. The substrate processing apparatus of claim 2, further comprising a second cleaning gas supply system configured to supply the cleaning gas into the shower head buffer chamber, and wherein the control member is configured to control the inert gas supply system, the first cleaning gas supply system and the second cleaning gas supply system to perform: (a) supplying the cleaning gas into the shower head buffer chamber by the second cleaning gas supply system and (b) supplying the cleaning gas into the processing space by the first cleaning gas supply system and the inert gas into the shower head buffer chamber by the inert gas supply system.

4. The substrate processing apparatus of claim 3, further comprising:
a first gas exhaust system including a first valve and configured to control the first valve to be closed in (a) and open in (b); and
a second gas exhaust system including a second valve and configured to control the second valve to be open in (a) and closed in (b).

5. The substrate processing apparatus of claim 4, wherein the control member is configured to control the inert gas supply system, the first cleaning gas supply system and the second cleaning gas supply system to repeat (a) and (b) alternately.

6. The substrate processing apparatus of claim 3, wherein the control member is configured to control the inert gas supply system, the first cleaning gas supply system and the second cleaning gas supply system to repeat (a) and (b) alternately.

7. The substrate processing apparatus of claim 1, further comprising a second cleaning gas supply system configured to supply the cleaning gas into the shower head buffer chamber, and wherein the control member is configured to control the inert gas supply system, the first cleaning gas supply system and the second cleaning gas supply system to perform: (a) supplying the cleaning gas into the shower head buffer chamber by the second cleaning gas supply system and (b) supplying the cleaning gas into the processing space by the first cleaning gas supply system and the inert gas into the shower head buffer chamber by the inert gas supply system.

8. The substrate processing apparatus of claim 7, further comprising:
a first gas exhaust system including a first valve and configured to control the first valve to be closed in (a) and open in (b); and
a second gas exhaust system including a second valve and configured to control the second valve to be open in (a) and closed in (b).

9. The substrate processing apparatus of claim 8, wherein the control member is configured to control the inert gas supply system, the first cleaning gas supply system and the second cleaning gas supply system to repeat (a) and (b) alternately.

10. The substrate processing apparatus of claim 7, wherein the control member is configured to control the inert gas supply system, the first cleaning gas supply system and the second cleaning gas supply system to repeat (a) and (b) alternately.

11. A substrate processing apparatus comprising:
a processing space for processing a substrate placed on a substrate placing surface;
a shower head buffer chamber communicating with the processing space through through-holes of a dispersion plate disposed above the substrate placing surface, the shower head buffer chamber comprising a gas guide configured to guide a gas supplied from above the dispersion plate toward the processing space;
an inert gas supply system configured to supply an inert gas to form a gas curtain in the shower head buffer chamber between the gas guide and the dispersion plate;
a first cleaning gas supply system configured to supply a cleaning gas into the processing space;
a second cleaning gas supply system configured to supply the cleaning gas into the shower head buffer chamber;
a first gas exhaust system configured to exhaust a gas in the shower head buffer chamber;
a second gas exhaust system configured to exhaust a gas in the processing space; and
a control member configured to control the first cleaning gas supply system, the second cleaning gas supply system, the inert gas supply system, the first gas exhaust system and the second gas exhaust system to concurrently supply at least the cleaning gas into the processing space and the inert gas into the shower head buffer chamber.

12. The substrate processing apparatus of claim 11, wherein the control member is configured to control the first cleaning gas supply system, the second cleaning gas supply system, the inert gas supply system, the first gas exhaust system and the second gas exhaust system to perform: (a) supplying the cleaning gas into the shower head buffer chamber by the second cleaning gas supply system and (b) supplying the cleaning gas into the processing space by the first cleaning gas supply system and the inert gas into the shower head buffer chamber by the inert gas supply system.

13. The substrate processing apparatus of claim 12, wherein the control member is configured to control the first cleaning gas supply system, the second cleaning gas supply system, the inert gas supply system, the first gas exhaust system and the second gas exhaust system to close a first valve of the first gas exhaust system and open a second valve of the second gas exhaust system in (a), and open the first valve and close the second valve in (b).

14. The substrate processing apparatus of claim 12, wherein the control member is configured to control the first cleaning gas supply system, the second cleaning gas supply system, the inert gas supply system, the first gas exhaust system and the second gas exhaust system to open a first valve of the first gas exhaust system and a second valve of the second gas exhaust system in (a), and open the first valve and close the second valve in (b).

15. The substrate processing apparatus of claim 12, wherein the control member is configured to control the first cleaning gas supply system, the second cleaning gas supply system, the inert gas supply system, the first gas exhaust system and the second gas exhaust system to open a first valve of the first gas exhaust system and a second valve of the second gas exhaust system in (a), and open the first valve and the second valve in (b).

16. The substrate processing apparatus of claim 12, wherein the control member is configured to control the first cleaning gas supply system, the second cleaning gas supply system, the inert gas supply system, the first gas exhaust system and the second gas exhaust system to close a first valve of the first gas exhaust system and open a second valve of the second gas exhaust system in (a), and open the first valve and the second valve in (b).

17. The substrate processing apparatus of claim 11, wherein the control member is configured to control the first cleaning gas supply system, the second cleaning gas supply system, the inert gas supply system, the first gas exhaust system and the second gas exhaust system to repeat (a) and (b) alternately.
